(19) United States
(12) Patent Application Publication
(10) Pub. No.: US 2026/0006992 A1
(43) Pub. Date: Jan. 1, 2026

(54) DISPLAY DEVICE AND ELECTRONIC DEVICE COMPRISING DISPLAY DEVICE

(71) Applicant: Samsung Display Co., Ltd., Yongin-si (KR)

(72) Inventors: Yong Hee LEE, Yongin-si (KR); Kyung Bae KIM, Yongin-si (KR); Dong Woo KIM, Yongin-si (KR); Yeon Kyung KIM, Yongin-si (KR)

(21) Appl. No.: 19/210,806

(22) Filed: May 16, 2025

(30) Foreign Application Priority Data
Jul. 1, 2024 (KR) 10-2024-0086409

(51) Int. Cl. H10K 59/121

(52) U.S. Cl. CPC H10K 59/1216; H10K 59/1213

(57) ABSTRACT

A display device according to one or more embodiments of the present disclosure includes: a pixel circuit layer including a conductive structure layer on a substrate; and a light-emitting element on the pixel circuit layer, wherein the conductive structure layer includes: a first and second base portion, extending in a first direction, the first and second base portion being spaced apart; first protrusion portions extending in a second direction; second protrusion portions extending in the second direction; and a first middle portion extending in the second direction, wherein a portion of the first and second protrusion portions are in a first capacitance area, and face each other, wherein a portion of the first and second protrusion portions are in a second capacitance area spaced apart from the first capacitance area, and face each other, and wherein the first middle portion is between the first and second capacitance area.

### CROSS-REFERENCE TO RELATED APPLICATION

The present application claims priority to and the benefit of Korean Patent Application No. 10-2024-0086409, filed on Jul. 1, 2024, in the Korean Intellectual Property Office, the entire disclosure of which is incorporated herein by reference.

### BACKGROUND

### 1. Field

Aspects of the present disclosure generally relate to a display device and an electronic device comprising the display device.

### 2. Description of the Related Art

Recently, as interest in information displays is increased, research and development of display devices have been continuously conducted.

A display device includes various circuit elements for driving a pixel. The circuit elements include a capacitor capable of storing charges and supplying charges necessary for an operation of a semiconductor element or the like.

In order for the display device to have high resolution characteristics, it is necessary to decrease the size of an area in which the circuit elements are formed. It may be difficult to sufficiently secure a capacitance of the capacitor per unit area, and it may be difficult to thoroughly control the magnitude of capacitance in a circuit element under such a manufacturing environment.

The above information disclosed in this Background section is only for enhancement of understanding of the background of the invention, and therefore, it may contain information that does not form the prior art.

### SUMMARY

Aspects of some embodiments of the present disclosure are directed to a display device in which the magnitude of capacitance of a capacitor can be thoroughly controlled, thereby improving the reliability of an electrical signal in the display device.

Aspects of some embodiments of the present disclosure are directed to a display device capable of having high resolution characteristics.

Aspects of embodiments of the present disclosure are directed to a display device in which an area having a circuit element disposed therein can be efficiently used.

According to some embodiments of the present disclosure, there is provided a display device including: a pixel circuit layer including a conductive structure layer on a substrate; and a light-emitting element on the pixel circuit layer, wherein the conductive structure layer includes: a first base portion and a second base portion, extending in a first direction, the first base portion and the second base portion being spaced apart from each other; first protrusion portions extending in a second direction different from the first direction, the first protrusion portions being integral with the first base portion; second protrusion portions extending in the second direction, the second protrusion portions being integral with the second base portion; and a first middle portion extending in the second direction, wherein a portion of the first protrusion portions and a portion of the second protrusion portions are in a first capacitance area, and face each other, wherein a portion of the first protrusion portions and a portion of the second protrusion portions are in a second capacitance area spaced apart from the first capacitance area in the first direction, and face each other, and wherein the first middle portion is between the first capacitance area and the second capacitance area.

In some embodiments, the first middle portion may be integrally formed with the first base portion, the first base portion, the first protrusion portions, and the first middle portion may form a first node portion to which a first charge information is provided, and the second base portion and the second protrusion portions may form a second node portion to which a second charge information is provided, the second charge information being different from the first charge information.

In some embodiments, some of the first protrusion portions, which are in the first capacitance area, and others of the first protrusion portions, which are in the second capacitance area, may have different lengths, and some of the second protrusion portions, which are in the first capacitance area, and some others of the second protrusion portions, which are in the second capacitance area, may have different lengths.

In some embodiments, a first side of the first middle portion may face one of the second protrusion portions in the first capacitance area, and a second side of the first middle portion may face one of the second protrusion portions in the second capacitance area.

In some embodiments, the second base portion may include a (2-1)th base portion and a (2-2)th base portion, which are spaced apart from the first base portion at different distances with respect to the second direction.

In some embodiments, the first middle portion may overlap with the second protrusion portions in the first capacitance area and the second capacitance area along the first direction, and the first middle portion may not overlap with the (2-1)th base portion and the (2-2)th base portion along the first direction.

In some embodiments, an end portion of the first middle portion may overlap with the second protrusion portions in the first capacitance area and the second capacitance area along the first direction, and may not overlap with the (2-1)th base portion and the (2-2)th base portion along the first direction, and the first middle portion may not overlap with the (2-1)th base portion and the (2-2)th base portion along the second direction.

In some embodiments, the first middle portion may overlap with the second protrusion portions in the first capacitance area along the first direction, and entirely overlap with the second protrusion portions in the second capacitance area along the first direction.

In some embodiments, an end portion of the first middle portion may overlap with the second protrusion portions in the first capacitance area along the first direction, and may not overlap with the second protrusion portions in the second capacitance area and the (2-2)th base portion along the first direction, and the first middle portion may not overlap with the (2-1)th base portion and the (2-2)th base portion along the second direction.

In some embodiments, the conductive structure layer may further include: a third base portion and a fourth base portion, extending in the first direction, the third base portion and the fourth base portion, being spaced apart from each other; third protrusion portions extending in the second direction, the third protrusion portions being integrally formed with the third base portion; fourth protrusion portions extending in the second direction, the fourth protrusion portions being integrally formed with the fourth base portion; and a second middle portion extending in the second direction, wherein some of the third protrusion portions and some of the fourth protrusion portions are in a third capacitance area, and face each other, wherein others of the third protrusion portions and others of the fourth protrusion portions are in a fourth capacitance area spaced apart from the third capacitance area in the first direction, and face each other, wherein an end portion of the second middle portion is between the third capacitance area and the fourth capacitance area, wherein the first capacitance area and the third capacitance area are adjacent to each other in the second direction, and wherein the second capacitance area and the fourth capacitance area are adjacent to each other in the second direction.

In some embodiments, the conductive structure layer may further include a body portion at one edge of the first base portion and the third base portion, the body portion being integrally formed with the first base portion and the third base portion, and the fourth base portion may include a (4-1)th base portion and a (4-2)th base portion, which are spaced apart from the third base portion at different distances along the second direction.

In some embodiments, the second middle portion may overlap with the fourth protrusion portions in the third capacitance area and the fourth capacitance area along the first direction, and may not overlap with the (4-1)th base portion and the (4-2)th base portion along the first direction, and the second middle portion may not overlap with the (4-1)th base portion and the (4-2)th base portion along the second direction.

In some embodiments, the second middle portion may overlap with the fourth protrusion portions in the third capacitance area and the fourth capacitance area along the first direction, may not overlap with the (4-1)th base portion along the first direction, and may overlap with the (4-2)th base portion along the first direction, and the second middle portion may not overlap with the (4-1)th base portion and the (4-2)th base portion along the second direction.

In some embodiments, the pixel circuit layer may include a sub-pixel circuit electrically connected to the light-emitting element, the sub-pixel circuit being formed by conductive layers on the substrate, and the conductive structure layer may include conductive structure layers on the conductive layers, the conductive structure layers being formed in a plurality of different layers.

In some embodiments, the conductive structure layer may include an ith conductive structure layer and an (i+1)th conductive structure layer, which are adjacent to each other in a thickness direction of the substrate, and the ith conductive structure layer and the (i+1)th conductive structure layer may form a capacitance along the thickness direction.

In some embodiments, the conductive structure layer may include an ith conductive structure layer and an (i+1)th conductive structure layer, which are adjacent to each other in a thickness direction of the substrate, and the ith conductive structure layer and the (i+1)th conductive structure layer may not form any capacitance along the thickness direction.

In some embodiments, the conductive structure layers may include a first conductive structure layer, a second conductive structure layer, a third conductive structure layer, and a fourth conductive structure layer, which are arranged in different layers.

In some embodiments, the pixel circuit layer may include a sub-pixel circuit, wherein the sub-pixel circuit includes: a first transistor connected between a first node and a second node, the first transistor including a gate electrode connected to a third node; a second transistor connected between a data line and the third node, the second transistor including a gate electrode electrically connected to a first sub-gate line; a third transistor connected between a first power line to which a first power voltage is supplied and the first node, the third transistor including a gate electrode electrically connected to an emission control line; a fourth transistor connected between the second node and a third power line to which an initialization voltage is supplied, the fourth transistor including a gate electrode electrically connected to a second sub-gate line; a first capacitor connected between the first node and the third node; a second capacitor connected between the third node and a fourth power line to which a reference voltage is supplied; and a third capacitor between the second node and the third node, wherein the light-emitting element is connected between the second node and a second power line to which a second power voltage is supplied, and wherein a first portion of the conductive structure layer forms one of the first node, the second node, and the third node, and a second portion of the conductive structure layer forms another of the first node, the second node, and the third node.

In some embodiments, the substrate may include silicon, and the light-emitting element may be an organic light emitting diode.

According to some embodiments of the disclosure, there is provided a display device including: a pixel circuit layer including a conductive structure layer on a substrate; and a light-emitting element on the pixel circuit layer, wherein the conductive structure layer includes: a first base portion and a second base portion, extending in a first direction, the first base portion and the second base portion, being spaced apart from each other; first protrusion portions extending in a second direction different from the first direction, the first protrusion portions being integrally formed with the first base portion; second protrusion portions extending in the second direction, the second protrusion portions being integrally formed with the second base portion; and a middle portion extending in the second direction, wherein the first protrusion portions, the second protrusion portions, the first base portion, and the second base portion are in capacitance areas adjacent to each other, wherein the middle portion is between the adjacent capacitance areas, and wherein the second base portion includes a (2-1)th base portion and a (2-2)th base portion, which are spaced apart from the first base portion at different distances.

According to some embodiments of the disclosure, there is provided an electronic device including: a processor configured to provide input image data; a display device configured to display an image based on the input image data; and a power supply configured to supply power to the display device, wherein the display device including: a pixel circuit layer including a conductive structure layer on a substrate; and a light-emitting element on the pixel circuit layer, wherein the conductive structure layer includes: a first base portion and a second base portion, extending in a first direction, the first base portion and the second base portion being spaced apart from each other; first protrusion portions extending in a second direction different from the first direction, the first protrusion portions being integral with the first base portion; second protrusion portions extending in the second direction, the second protrusion portions being integral with the second base portion; and a first middle portion extending in the second direction, wherein a portion of the first protrusion portions and a portion of the second protrusion portions are in a first capacitance area, and face each other, wherein a portion of the first protrusion portions and a portion of the second protrusion portions are in a second capacitance area spaced apart from the first capacitance area in the first direction, and face each other, and wherein the first middle portion is between the first capacitance area and the second capacitance area.

### BRIEF DESCRIPTION OF THE DRAWINGS

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the example embodiments to those skilled in the art.

In the drawing figures, dimensions may be exaggerated for clarity of illustration. It will be understood that when an element is referred to as being “between” two elements, it can be the only element between the two elements, or one or more intervening elements may also be present. Like reference numerals refer to like elements throughout.

FIG. 1 is a block diagram illustrating a display device according to some embodiments of the present disclosure.

FIG. 2 is a block diagram illustrating any one of sub-pixels shown in FIG. 1 according to some embodiments of the present disclosure.

FIG. 3 is a schematic diagram illustrating a sub-pixel circuit and a sub-pixel including the same according to some embodiments of the present disclosure.

FIG. 4 is a plan view illustrating a display panel shown in FIG. 1 according to some embodiments of the present disclosure.

FIG. 5 is an exploded perspective view illustrating a portion of the display panel shown in FIG. 4 according to some embodiments of the present disclosure.

FIG. 6 is a schematic sectional view illustrating a pixel circuit layer according to some embodiments of the present disclosure.

FIGS. 7 to 10 are schematic plan views illustrating a conductive structure layer according to some embodiments of the present disclosure.

FIGS. 11 and 12 are schematic views illustrating a capacitance relationship between conductive structure layers adjacent to each other in a vertical direction according to some embodiments of the present disclosure.

FIG. 13 is a block diagram illustrating an electronic device according to some embodiments of the present disclosure.

FIG. 14 is a perspective view illustrating an application example of the electronic device shown in FIG. 13 according to some embodiments of the present disclosure.

FIG. 15 is a view illustrating a head-mounted display device shown in FIG. 14, which is worn by a user, according to some embodiments of the present disclosure.

### DETAILED DESCRIPTION

Hereinafter, embodiments will be described in more detail with reference to the accompanying drawings, in which like reference numbers refer to like elements throughout. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described. Unless otherwise noted, like reference numerals denote like elements throughout the attached drawings and the written description, and thus, redundant description thereof may not be repeated.

When a certain embodiment may be implemented differently, a specific process order may be different from the described order. For example, two consecutively described processes may be performed at the same or substantially at the same time, or may be performed in an order opposite to the described order.

In the drawings, the relative sizes, thicknesses, and ratios of elements, layers, and regions may be exaggerated and/or simplified for clarity. Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

In the figures, the x-axis, the y-axis, and the z-axis (or DR1, DR2, and DR3) are not limited to three axes of the rectangular coordinate system, and may be interpreted in a broader sense. For example, the x-axis, the y-axis, and the z-axis (or DR1, DR2, and DR3) may be perpendicular to or substantially perpendicular to one another, or may represent different directions from each other that are not perpendicular to one another.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

It will be understood that when an element or layer is referred to as being “on,” “connected to,” or “coupled to” another element or layer, it can be directly on, connected to, or coupled to the other element or layer, or one or more intervening elements or layers may be present. Similarly, when a layer, an area, or an element is referred to as being “electrically connected” to another layer, area, or element, it may be directly electrically connected to the other layer, area, or element, and/or may be indirectly electrically connected to the other layer, area, or element, with one or more intervening layers, areas, or elements therebetween. In addition, it will also be understood that when an element or layer is referred to as being “between” two elements or layers, it can be the only element or layer between the two elements or layers, or one or more intervening elements or layers may also be present.

The terminology used herein is for the purpose of describing particular embodiments and is not intended to be limiting of the present disclosure. As used herein, the singular forms “a” and “an” are intended to include the plural forms as well, unless the context clearly indicates otherwise. It will be further understood that the terms “comprises,” “comprising,” “includes,” “including,” “has,” “have,” and “having,” when used in this specification, specify the presence of the stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. For example, the expression “A and/or B” denotes A, B, or A and B. Expressions such as “at least one of,” when preceding a list of elements, modify the entire list of elements and do not modify the individual elements of the list. For example, the expression “at least one of a, b, or c,” “at least one of a, b, and c,” and “at least one selected from the group consisting of a, b, and c” indicates only a, only b, only c, both a and b, both a and c, both b and c, all of a, b, and c, or variations thereof.

As used herein, the term “substantially,” “about,” and similar terms are used as terms of approximation and not as terms of degree, and are intended to account for the inherent deviations in measured or calculated values that would be recognized by those of ordinary skill in the art. Further, the use of “may” when describing embodiments of the present disclosure refers to “one or more embodiments of the present disclosure.” As used herein, the terms “use,” “using,” and “used” may be considered synonymous with the terms “utilize,” “utilizing,” and “utilized,” respectively.

The electronic or electric devices and/or any other relevant devices or components according to embodiments of the present disclosure described herein may be implemented utilizing any suitable hardware, firmware (e.g. an application-specific integrated circuit), software, or a combination of software, firmware, and hardware. For example, the various components of these devices may be formed on one integrated circuit (IC) chip or on separate IC chips. Further, the various components of these devices may be implemented on a flexible printed circuit film, a tape carrier package (TCP), a printed circuit board (PCB), or formed on one substrate. Further, the various components of these devices may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the spirit and scope of the example embodiments of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

The present disclosure generally relates to a display device and an electronic device comprising the display device. Hereinafter, a display device and an electronic device comprising the display device in accordance with some embodiments of the present disclosure will be described with reference to the accompanying drawings.

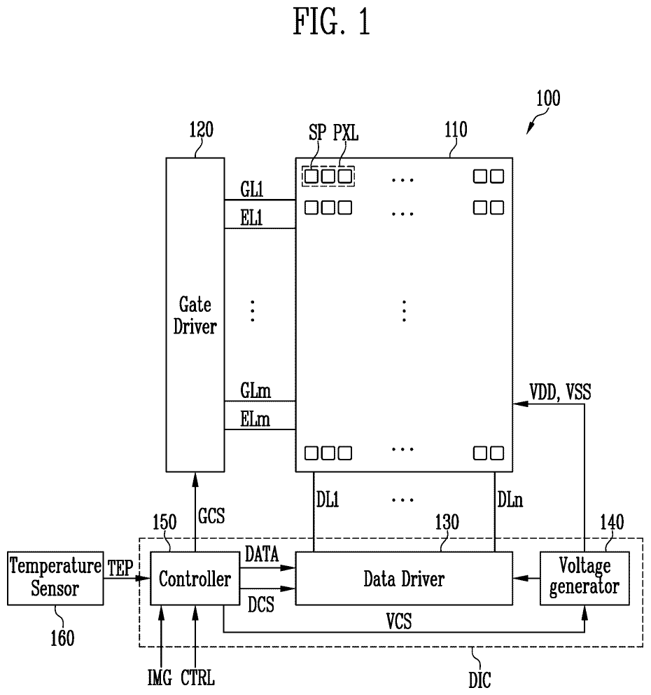

FIG. 1 is a block diagram illustrating a display device according to some embodiments of the present disclosure.

Referring to FIG. 1, the display device 100 may include a display panel 110, a gate driver 120, a data driver 130, a voltage generator 140, and a controller 150.

The display panel 110 may include sub-pixels SP. The sub-pixels SP may be connected to the gate driver 120 through first to mth gate lines GL1 to GLm. The sub-pixels SP may be connected to the data driver 130 through first to nth data lines DL1 to DLn.

Each of the sub-pixels SP may include at least one light-emitting element configured to generate light. Accordingly, each of the sub-pixels SP may generate light of a specific color, such as red, green, blue, cyan, magenta or yellow. Two or more sub-pixels SP among the sub-pixels SP may constitute a pixel PXL. For example, three sub-pixels SP may constitute a pixel PXL as shown in FIG. 1.

The gate driver 120 may be connected to the sub-pixels SP arranged in a row direction through the first to mth gate lines GL1 to GLm. The gate driver 120 may output gate signals to the first to mth gate lines GL1 to GLm in response to a gate control signal GCS. In some embodiments, the gate control signal GCS may include a start signal indicating a start of each frame, a horizontal synchronization signal for outputting gate signals in synchronization with timings at which data signals are applied, and/or the like.

In some embodiments, first to mth emission control lines EL1 to ELm connected to the sub-pixels SP arranged in the row direction may be further provided. The gate driver 120 may include an emission control driver configured to control the first to mth emission control lines EL1 to ELm, and the emission control driver may operate under the control of the controller 150.

The gate driver 120 may be disposed at a side of the display panel 110. However, embodiments are not limited thereto. For example, the gate driver 120 may be divided into two or more drivers which are physically and/or logically divided (e.g., separated), and these drivers may be disposed at a side of the display panel 110 and the other side of the display panel 110, which is opposite to the side. As such, in some embodiments, the gate driver 120 may be disposed in various suitable forms at the periphery of the display panel 110.

The data driver 130 may be connected to the sub-pixels SP arranged in a column direction through the first to nth data lines DL1 to DLn. The data driver 130 may receive image data DATA and a data control signal DCS from the controller 150. The data driver 130 may operate in response to the data control signal DCS. In some embodiments, the data control signal DCS may include a source start pulse, a source shift clock, a source output enable signal, and/or the like.

The data driver 130 may apply data signals having grayscale voltages corresponding to the image data DATA to the first to nth data lines DL1 to DLn by using voltages from the voltage generator 140. When a gate signal is applied to each of the first to mth gate lines GL1 to GLm, data signals corresponding to the image data DATA may be applied to the data lines DL1 to DLn. Accordingly, corresponding sub-pixels SP may generate light corresponding to the data signals. Accordingly, an image may be displayed on the display panel 110.

In some embodiments, the gate driver 120 and the data driver 130 may include complementary metal-oxide semiconductor (CMOS) circuit elements.

The voltage generator 140 may operate in response to a voltage control signal VCS from the controller 150. The voltage generator 140 may be configured to generate a plurality of voltages and provide the generated voltages to components of the display device 100. For example, the voltage generator 140 may be configured to generate a plurality of voltages by receiving an input voltage from an outside of the display device 100, adjusting the received voltage, and regulating the adjusted voltage.

The voltage generator 140 may generate a first power voltage VDD and a second power voltage VSS, and the generated first and second power voltages VDD and VSS may be provided to the sub-pixels SP. The first power voltage VDD may have a relatively high voltage level, and the second power voltage VSS may have a voltage level lower than the voltage level of the first power voltage VDD (e.g., a low voltage or a relatively low voltage). In some other embodiments, the first power voltage VDD or the second power voltage VSS may be provided by an external device of the display device 100.

The voltage generator 140 may generate various suitable voltages. For example, the voltage generator 140 may generate an initialization voltage applied to the sub-pixels SP. For example, a set (e.g., preset or predetermined) reference voltage may be applied to the first to nth data lines DL1 to DLn in a sensing operation for sensing electrical characteristics of transistors and/or light-emitting elements of the sub-pixels SP, and the voltage generator 140 may generate the reference voltage.

The controller 150 may control overall operations of the display device 100. The controller 150 may receive, from the outside, input image data IMG and a control signal CTRL for controlling display thereof. The controller 150 may provide the gate control signal GCS, the data control signal DCS, and the voltage control signal VCS in response to the control signal CTRL.

The controller 150 may convert the input image data IMG to be suitable for the display device 100 or the display panel 110, thereby outputting the image data DATA. In some embodiments, the controller 150 may align the input image data IMG to be suitable for the sub-pixels SP in units of rows, thereby outputting the image data DATA.

Two or more components among the data driver 130, the voltage generator 140, and the controller 150 may be mounted on an integrated circuit. As shown in FIG. 1, the data driver 130, the voltage generator 140, and the controller 150 may be included in a driver integrated circuit DIC. The data driver 130, the voltage generator 140, and the controller 150 may be components functionally divided in a driver integrated circuit DIC. In some other embodiments, at least one of the data driver 130, the voltage generator 140, and the controller 150 may be provided as a component distinguished from the driver integrated circuit DIC.

The display device 100 may include at least one temperature sensor 160. The temperature sensor 160 may be configured to sense a temperature at the periphery thereof and generate temperature data TEP indicating the sensed temperature. In some embodiments, the temperature sensor 160 may be disposed to be adjacent to the display panel 110 and/or the driver integrated circuit DIC.

The controller 150 may control various operations of the display device 100 in response to the temperature data TEP. In some embodiments, the controller 150 may adjust a luminance of an image output from the display device 100 in response to the temperature data TEP. For example, the controller 150 may control components such as the data driver 130 and/or the voltage generator 140, thereby adjusting data signals and the first and second power voltages VDD and VSS.

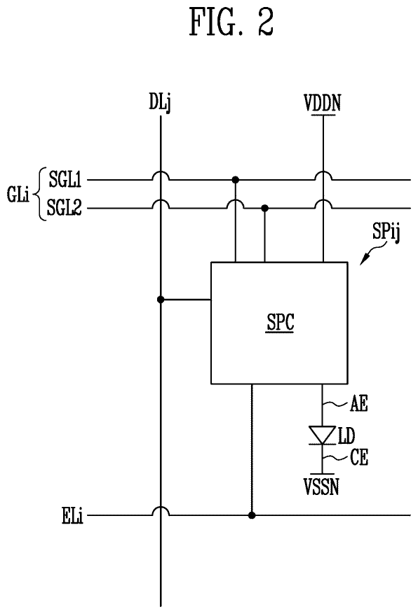

FIG. 2 is a block diagram illustrating any one of the sub-pixels shown in FIG. 1 according to some embodiments of the present disclosure. In FIG. 2, a sub-pixel SPij arranged on an ith row (where i is an integer greater than or equal to 1 and smaller than or equal to m) and a jth column (where j is an integer greater than or equal to 1 and smaller than or equal to n) among the sub-pixels SP shown in FIG. 1 is illustrated.

Referring to FIG. 2, the sub-pixel SPij may include a sub-pixel circuit SPC and a light-emitting element LD.

The light-emitting element LD may be connected between a first power voltage node VDDN and a second power voltage node VSSN. The first power voltage node VDDN may be a node transferring the first power voltage VDD shown in FIG. 1, and the second power voltage node VSSN may be a node transferring the second power voltage VSS shown in FIG. 1.

An anode electrode AE of the light-emitting element LD may be connected to the first power voltage node VDDN through the sub-pixel circuit SPC, and a cathode electrode CE of the light-emitting element LD may be connected to the second power voltage node VSSN. For example, the anode electrode AE of the light-emitting element LD may be connected to the first power voltage node VDDN through one or more transistors included in the sub-pixel circuit SPC.

The sub-pixel circuit SPC may be connected to an ith gate line GLi among the first to mth gate lines GL1 to GLm shown in FIG. 1, an ith emission control line ELi among the first to mth emission control lines EL1 to ELm shown in FIG. 1, and a jth data line DLj among the first to nth data lines DL1 to DLn shown in FIG. 1. The sub-pixel circuit SPC may be configured to control the light-emitting element LD according to signals received through these signal lines.

The sub-pixel circuit SPC may operate in response to a gate signal received through the ith gate line GLi. The ith gate line GLi may include one or more sub-gate lines. In some embodiments, as shown in FIG. 2, the ith gate line GLi may include first and second sub-gate lines SGL1 and SGL2. The sub-pixel circuit SPC may operate in response to gate signals received through the first and second sub-gate lines SGL1 and SGL2. As such, when the ith gate line GLi includes two or more sub-gate lines, the sub-pixel circuit SPC may operate in response to gate signals received through the corresponding sub-gate lines.

The sub-pixel circuit SPC may operate in response to an emission control signal received through the ith emission control line ELi. In some embodiments, the ith emission control line ELi may include one or more sub-emission control lines. When the ith emission control line ELi includes two or more sub-emission control lines, the sub-pixel circuit SPC may operate in response to emission control signals receives through the corresponding emission control lines.

The sub-pixel circuit SPC may receive a data signal through the jth data line DLj. The sub-pixel circuit SPC may store a voltage corresponding to the data signal in response to at least one of the gate signals received through the first and second sub-gate lines SGL1 and SGL2. The sub-pixel circuit SPC may control a current flowing from the first power voltage node VDDN to the second power voltage node VSSN through the light-emitting element LD according to the stored voltage in response to the emission control signal received through the ith emission control line ELi. Accordingly, the light-emitting element LD may generate light with a luminance corresponding to the data signal.

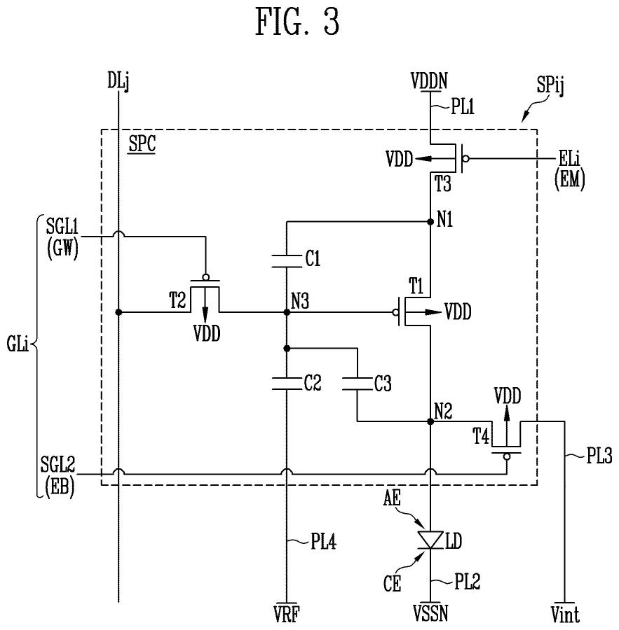

FIG. 3 is a schematic diagram illustrating a sub-pixel circuit and a sub-pixel including the same according to some embodiments of the present disclosure. Similar to FIG. 2, FIG. 3 illustrates a sub-pixel SPij located on an ith horizontal line and a jth vertical line among the sub-pixels SP.

Referring to FIG. 3, a sub-pixel circuit SPC may include a first transistor T1, a second transistor T2, a third transistor T3, a fourth transistor T4, a first capacitor C1, a second capacitor C2, and a third capacitor C3.

A light-emitting element LD may include an anode electrode AE and a cathode electrode CE. The anode electrode AE may be electrically connected to the sub-pixel circuit SPC through a second node N2, and be electrically connected to a first power line PL1 to which the first power voltage VDD is supplied. The cathode electrode CE may be electrically connected to a second power line PL2 to which the second power voltage VSS is supplied.

The first to fourth transistors T1 to T4 may be transistors each including a body electrode. For example, each of the first to fourth transistors T1 to T4 may be a metal oxide semiconductor field effect transistor (MOSFET). The first to fourth transistors T1 to T4 may be mounted in a narrow area, and accordingly, the sub-pixel SPij may be applied to a high resolution panel. The body electrode of each of the first to fourth transistors T1 to T4 may be supplied with the first power voltage VDD. In some embodiments, the body electrode of each of the first to fourth transistors T1 to T4 may be electrically connected to the first power line PL1 to which the first power voltage VDD is supplied.

In some embodiments, the first to fourth transistors T1 to T4 may be implemented with a P-type transistor. However, this is merely illustrative, and at least one of the first to fourth transistors T1 to T4 may be an N-type transistor.

A first electrode of the first transistor T1 may be connected to a first node N1, and a second electrode of the first transistor T1 may be connected to a second node N2. In the present disclosure, the term “being connected” may include being electrically connected. A gate electrode of the first transistor T1 may be connected to a third node N3. The first node N1 may be a node to which a second electrode of the third transistor T3 is connected, and the second node N2 may be a node to which a first electrode (i.e., the anode electrode AE) of the light-emitting element LD is connected. The first transistor T1 may control an amount of current supplied from the first power voltage VDD to the second power voltage VSS via the light-emitting element LD.

The second transistor T2 may be connected between a data line DLj and the third node N3. In addition, a gate electrode of the second transistor T2 may be electrically connected to a first sub-gate line SGL1. The second transistor T2 may be turned on when a first gate signal GW is supplied to the first sub-gate line SGL1, to electrically connect the data line DLj and the third node N3 to each other.

A first electrode of the third transistor T3 may be electrically connected to the first power line PL1, and the second electrode of the third transistor T3 may be connected to the first node N1. In addition, a gate electrode of the third transistor T3 may be electrically connected to an emission control line ELi. The third transistor T3 may be turned off when an emission control signal EM is supplied to the emission control line ELi, and be turned on when the emission control signal EM is not supplied. When the third transistor T3 is turned off, the first power line PL1 and the first node N1 may be electrically interrupted from each other.

A first electrode of the fourth transistor T4 may be connected to the second node N2, and a second electrode of the fourth transistor T4 may be electrically connected to a third power line PL3 to which an initialization power Vint (e.g., an initialization voltage) is supplied. In addition, a gate electrode of the fourth transistor T4 may be electrically connected to a second sub-gate line SGL2. The fourth transistor T4 may be turned on when a second gate signal EB is supplied to the second sub-gate line SGL2, to electrically connect the second node N2 and the third power line PL3 to each other.

The first capacitor C1 may be connected between the first node N1 and the third node N3. The first capacitor C1 may transfer a voltage variation of the first node N1 to the third node N3 while being driven as a coupling capacitor. Also, the first capacitor C1 may store the voltage of the third node N3.

The second capacitor C2 may be connected between the third node N3 and a fourth power line PL4 to which a reference power VRF (e.g., a reference voltage) is supplied. A voltage level of the reference power VRF may be determined within a range in which the voltage level does not exceed a maximum voltage which the second capacitor C2 can have (e.g., a threshold voltage). In some embodiments, the voltage level of the reference power VRF may be lower than a voltage level of the first power voltage VDD and may be higher than a voltage level of the initialization power Vint.

In some other embodiments, the voltage level of the reference power VRF may be equal to the voltage level of the first power voltage VDD. The second capacitor C2 may be connected between the third node N3 and the first power line PL1 to which the first power voltage VDD is supplied.

The third capacitor C3 may be connected between the second node N2 and the third node N3. The third capacitor C3 may transfer a voltage variation of the second node N2 to the third node N3 while being driven as a coupling capacitor.

In some embodiments, each of the first to third capacitors C1 to C3 may have a structure of one of a metal-oxide-metal (MOM) capacitor and a metal-insulator-metal (MIM) capacitor. In some embodiments, at least one of the first to third capacitors C1 to C3 may have a vertical native capacitor (VNCAP) structure. However, the present disclosure is not necessarily limited to a specific example.

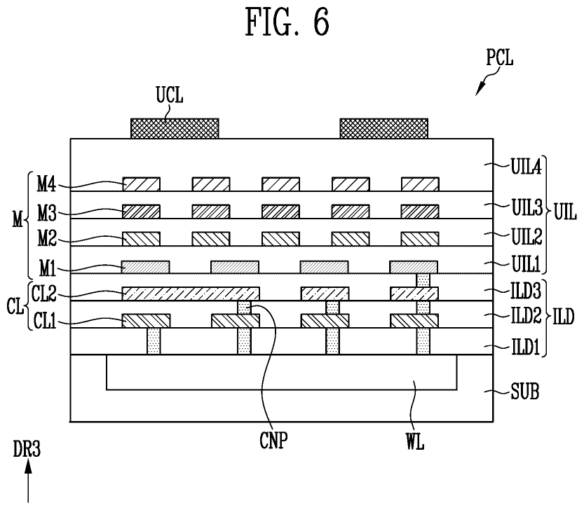

In some embodiments, each of the first to third capacitors C1 to C3 may secure a sufficient capacitance, and have a structure including multi-capacitance formation areas in which a capacitance magnitude can be suitably adjusted. This will be described in detail later with reference to FIG. 6.

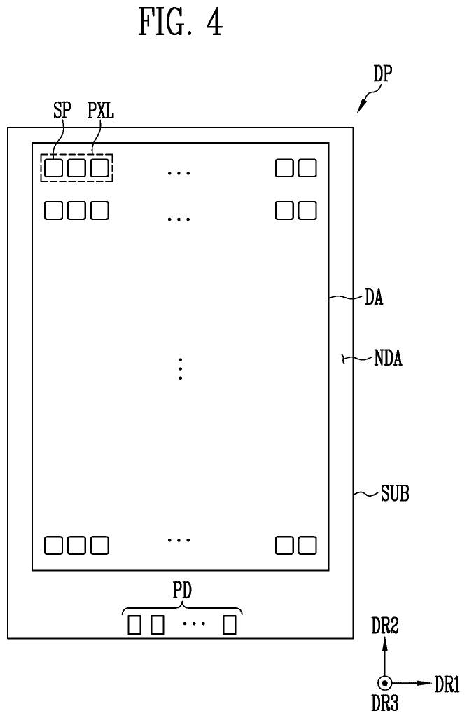

FIG. 4 is a plan view illustrating the display panel shown in FIG. 1 according to some embodiments of the present disclosure.

Referring to FIG. 4, a display panel of some embodiments of the display panel 110 shown in FIG. 1 may include a display area DA and a non-display area NDA. The display panel DP may display an image through the display area DA. The non-display area NDA may be disposed at a periphery of the display area DA.

The display panel DP may include a substrate SUB, sub-pixels SP, or pads PD.

When the display panel DP is used as a display screen of a Head Mounted Display (HMD), a Virtual Reality (VR) device, a Mixed Reality (MR) device, an Augmented Reality (AR) device, or the like, the display panel DP may be located very close to eyes of a user. In some embodiments, the sub-pixels SP may have a relatively high degree of integration (e.g., a high resolution or a high pixel density). In order to increase the degree of integration of the sub-pixels SP, the substrate SUB may be provided as a silicon substrate. The sub-pixels SP and/or the display panel DP may be formed on the substrate SUB as the silicon substrate. The display device 100 including the display panel DP formed on the substrate SUB as the silicon substrate may be designated as an OLED on Silicon (OLEDoS) display device.

The sub-pixels SP may be disposed in the display area DA on the substrate SUB. The sub-pixels SP may be arranged in a matrix form (e.g., grid form) along a first direction DR1 and a second direction DR2 intersecting the first direction DR1. However, embodiments are not limited thereto. For example, the sub-pixels SP may be arranged in a zigzag form along the first direction DR1 and the second direction DR2. For example, the sub-pixels SP may be disposed in a PENTILE™ form. The first direction DR1 may be a row direction, and the second direction DR2 may be a column direction.

Two or more sub-pixels SP among the sub-pixels SP may constitute a pixel PXL.

A component for controlling the sub-pixels SP may be disposed in the non-display area NDA on the substrate SUB. For example, lines connected to the sub-pixels SP, such as the first to mth gate lines GL1 to GLm and the first to nth data lines DL1 to DLn, which are shown in FIG. 1, may be disposed in the non-display area NDA.

At least one of the gate driver 120, the data driver 130, the voltage generator 140, the controller 150, and the temperature sensor 160, which are shown in FIG. 1, may be integrated in the non-display area NDA of the display panel DP. In some embodiments, the gate driver 120 shown in FIG. 1 may be mounted on the display panel DP, and may be disposed in the non-display area NDA. In some other embodiments, the gate driver 120 may be implemented as an integrated circuit distinguished from the display panel DP. In some embodiments, the temperature sensor 160 may be disposed in the non-display area NDA to sense a temperature of the display panel DP.

The pads PD may be disposed in the non-display area NDA on the substrate SUB. The pads PD may be electrically connected to the sub-pixels SP through the lines. For example, the pads PD may be connected to the sub-pixels SP through the first to nth data lines DL1 to DLn.

The pads PD may interface the display panel DP with other components of the display device 100. In some embodiments, voltages and signals, which may enable operations of components included in the display panel DP, may be provided from the driver integrated circuit DIC shown in FIG. 1 through the pads PD. For example, the first to nth data lines DL1 to DLn may be connected to the driver integrated circuit DIC through the pads PD. For example, the first and second power voltages VDD and VSS may be received from the driver integrated circuit DIC through the pads PD. When the gate driver 120 is mounted in the display panel DP, the gate control signal GCS may be transmitted from the driver integrated circuit DIC to the gate driver 120 through the pads PD.

In some embodiments, a circuit board may be electrically connected to the pads PD, using a conductive adhesive member such as an anisotropic conductive film. The circuit board may be a Flexible Printed Circuit Board (FPCB) or a flexible film, which has a flexible material. The driver integrated circuit DIC may be mounted on the circuit board to be electrically connected to the pads PD.

In some embodiments, the display area DA may have various suitable shapes. The display area DA may have a closed-loop shape including linear sides and/or curved sides. For example, the display area DA may have shapes such as a polygon, a circle, a semicircle, an ellipse, or the like.

In some embodiments, the display panel DP may have a flat display surface. In some other embodiments, the display panel DP may at least partially have a round display surface. In some embodiments, the display panel DP may be bendable, foldable, or rollable. The display panel DP and/or the substrate SUB may include materials having flexibility (e.g., materials that are flexible).

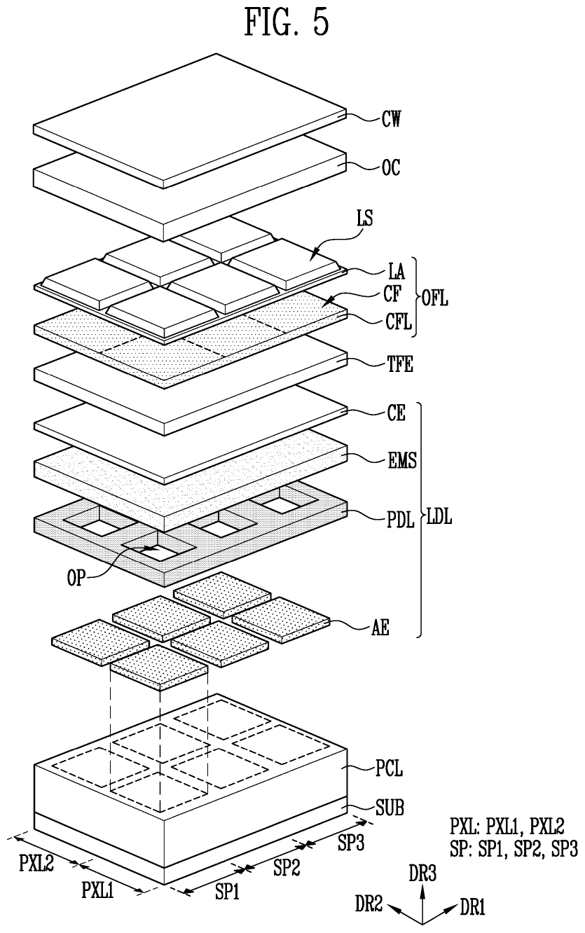

FIG. 5 is an exploded perspective view illustrating a portion of the display panel shown in FIG. 4 according to some embodiments of the present disclosure. In FIG. 5, for clear and brief description, a portion of the display panel DP, which corresponds to two pixels PXL1 and PXL2 among the pixels PXL shown in FIG. 4, may be schematically illustrated. A portion of the display panel DP, which corresponds to the other pixels PXL, may also be configured identically.

Referring to FIGS. 4 and 5, the pixel PXL may include first and second pixels PXL1 and PXL2. The sub-pixel SP may include first to third sub-pixels SP1 to SP3. Each of the first and second pixels PXL1 and PXL2 may include first to third sub-pixels SP1 to SP3. However, embodiments are not limited thereto. For example, each of the first and second pixels PXL1 and PXL2 may include four sub-pixels SP or may include two sub-pixels SP.

In FIG. 5, it may be illustrated that the first to third sub-pixels SP1, SP2, and SP3 may have quadrangular shapes when viewed in a third direction DR3 intersecting the first and second directions DR1 and DR2, and have the same size or substantially the same size. However, embodiments are not limited thereto. The first to third sub-pixels SP1, SP2, and SP3 may be modified to have various suitable shapes.

The display panel DP may include a substrate SUB, a pixel circuit layer PCL, a light-emitting element layer LDL, an encapsulation layer TFE, an optical functional layer OFL, an overcoat layer OC, and a cover window CW.

In some embodiments, the substrate SUB may include a silicon wafer substrate formed using a semiconductor process. The substrate SUB may include a semiconductor material suitable for forming circuit elements. For example, the semiconductor material may include silicon, germanium, and/or silicon-germanium. The substrate SUB may be provided from a bulk wafer, an epitaxial layer, a Silicon On Insulator (SOI) layer, a Semiconductor On Insulator (SeOI) layer, or the like. In some other embodiments, the substrate SUB may include a glass substrate. In still other embodiments, the substrate SUB may include a polyimide (PI) substrate.

The pixel circuit layer PCL may be disposed on the substrate SUB. The substrate SUB and/or the pixel circuit layer PCL may include insulating layers and conductive patterns disposed between the insulating layers. The conductive patterns of the pixel circuit layer PCL may serve as at least some of circuit elements, lines, and the like. The conductive patterns may include copper, but embodiments are not limited thereto.

The circuit elements may include a sub-pixel circuit SPC (see, e.g., FIG. 2) of each of the first to third sub-pixels SP1, SP2, and SP3. The sub-pixel circuit SPC may include transistors and one or more capacitors. Each transistor may include a semiconductor portion including a source region, a drain region, and a channel region, and a gate electrode overlapping with the semiconductor portion. In some embodiments, when the substrate SUB is provided as a silicon substrate, the semiconductor portion may be included in the substrate SUB, and the gate electrode may be included as a conductive pattern of the pixel circuit layer PCL in the pixel circuit layer PCL. In some embodiments, when the substrate SUB is provided as a glass substrate or a polyimide (PI) substrate, the semiconductor portion and the gate electrode may be included in the pixel circuit layer PCL. Each capacitor may include electrodes spaced apart from each other. For example, each capacitor may include electrodes spaced apart from each other on a plane defined by the first and second directions DR1 and DR2. For example, the capacitor may include electrodes spaced apart from each other in the third direction DR3 with an insulating layer interposed therebetween.

The lines of the pixel circuit layer PCL may include signal lines (e.g., a gate line, an emission control line, a data line, and the like), which are connected to each of the first to third sub-pixels SP1, SP2, and SP3. The lines may further include a line connected to the first power voltage node VDDN shown in FIG. 2. Also, the lines may further include a line connected to the second power voltage node VSSN shown in FIG. 2.

The light-emitting element layer LDL may include anode electrodes AE, a pixel defining layer PDL, an emission structure EMS, and a cathode electrode CE.

The anode electrodes AE may be disposed on the pixel circuit layer PCL. The anode electrodes AE may be in contact with the circuit elements of the pixel circuit layer PCL. The anode electrodes AE may include an opaque conductive material capable of reflecting light, but embodiments are not limited thereto.

The pixel defining layer PDL may be disposed over the anode electrodes AE. The pixel defining layer PDL may include an opening OP exposing a portion of each of the anode electrodes AE. Emission areas respectively corresponding to the first to third sub-pixels SP1 to SP3 may be defined according to the openings OP of the pixel defining layer PDL. In some embodiments, emission areas respectively corresponding to the first to third sub-pixels SP1 to SP3 may be defined according to the anode electrodes AE. In an area adjacent to a boundary between sub-pixels SP adjacent to each other, the pixel defining layer PDL may include a separator which causes a discontinuity to be formed in the emission structure EMS. In some embodiments, emission areas respectively corresponding to the first to third sub-pixels SP1 to SP3 may be defined according to separator of the pixel defining layer PDL.

In some embodiments, the pixel defining layer PDL may include an inorganic material. The pixel defining layer PDL may include a plurality of stacked inorganic layers. For example, the pixel defining layer PDL may include silicon oxide (SiOₓ) and silicon nitride (SiNₓ). In some other embodiments, the pixel defining layer PDL may include an organic material. However, the material of the pixel defining layer PDL is not limited thereto.

The emission structure EMS may be disposed on the anode electrodes AE exposed by the openings OP of the pixel defining layer PDL. The emission structure EMS may include a light emitting layer configured to generate light, an electron transport layer configured to transport electrons, a hole transport layer configured to transport holes, and the like.

In some embodiments, the emission structure EMS may fill the opening OP of the pixel defining layer PDL, and may be entirely disposed on the top of the pixel defining layer PDL. In other words, the emission structure EMS may extend throughout the first to third sub-pixels SP1 to SP3. At least some of the layers in the emission structure EMS may be cut or bent at boundaries between the first to third sub-pixels SP1 to SP3. However, embodiments are not limited thereto. For example, portions of the emission structure EMS, which correspond to the first to third sub-pixels SP1 to SP3, may be separated from each other, and each of the portions may be disposed in the opening OP of the pixel defining layer PDL.

The cathode electrode CE may be disposed on the emission structure EMS. The cathode electrode CE may extend throughout the first to third sub-pixels SP1 to SP3. As such, the cathode electrode CE may be provided as a common electrode for the first to third sub-pixels SP1 to SP3.

The cathode electrode CE may be a thin metal layer having a thickness to a degree to which light emitted from the emission structure EMS can be transmitted therethrough. For example, the cathode electrode CE may be thin enough that light may transmit through the cathode electrode CE. The cathode electrode CE may be formed of a metal material to have a relatively thin thickness (e.g., a relatively small thickness) or be formed of a transparent conductive material. In some embodiments, the cathode electrode CE may include at least one of various suitable transparent conductive materials including indium tin oxide, indium zinc oxide, indium tin zinc oxide, aluminum zinc oxide, gallium zinc oxide, zinc tin oxide, and gallium tin oxide. In some other embodiments, the cathode electrode CE may include at least one of silver (Ag), magnesium (Mg), or mixtures thereof. However, the material of the cathode electrode CE is not limited thereto.

It may be understood that any one of the anode electrodes AE, a portion of the emission structure EMS, which overlaps therewith, and a portion of the cathode electrode CE, which overlaps therewith, constitute a light-emitting element LD. In other words, each of light-emitting elements LD of the first to third sub-pixels SP1 to SP3 may include an anode electrode AE, a portion of the emission structure EMS, which overlaps therewith, and a portion of the cathode electrode CE, which overlaps therewith. In each of the first to third sub-pixels SP1 to SP3, holes injected from the anode electrode AE and electrons injected from the cathode electrode CE may be transported into a light emitting layer of the emission structure EMS to form excitons, and light may be generated when the excitons are changed from an excited state to a ground state. A luminance of the light may be determined according to an amount of current flowing through the light emitting layer. A wavelength band of the generated light may be determined according to a configuration of the light emitting layer.

In some embodiments, the light-emitting element LD may be an organic light emitting diode.

The encapsulation layer TFE may be disposed over the cathode electrode CE. The encapsulation layer TFE may cover the light-emitting element layer LDL and/or the pixel circuit layer PCL. The encapsulation layer TFE may be configured to prevent oxygen and/or moisture from infiltrating into the light-emitting element layer LDL. In some embodiments, the encapsulation layer TFE may include a structure in which at least one inorganic layer and at least one organic layer are alternately stacked. For example, the inorganic layer may include silicon nitride, silicon oxide, silicon oxynitride (SiOₓN_{y}), or the like. For example, the organic layer may include an organic insulating material such as acrylic resin, epoxy resin, phenolic resin, polyamide resin, polyimide resin, unsaturated polyester resin, polyphenylene resin, polyphenylene sulfide resin, benzocyclobutene (BCB) resin, or the like. However, the materials of the organic layer and the inorganic layer of the encapsulation layer TFE are not limited thereto.

In order to improve encapsulation efficiency of the encapsulation layer TFE, the encapsulation layer TFE may further include a thin film including aluminum oxide (AlOₓ). The thin film including the aluminum oxide may be located on a top surface of the encapsulation layer TFE, which faces the optical functional layer OFL, and/or a bottom surface of the encapsulation layer TFE, which faces the light-emitting element layer LDL.

The thin film including the aluminum oxide may be formed through an Atomic Layer Deposition (ALD) process. However, embodiments are not limited thereto. The encapsulation layer TFE may further include a thin film formed of at least one of various materials suitable for the improvement of the encapsulation efficiency.

The optical functional layer OFL may be disposed on the encapsulation layer TFE. The optical functional layer OFL may include a color filter layer CFL and a lens array LA.

The color filter layer CFL may be disposed between the encapsulation layer TFE and the lens array LA. The color filter layer CFL may be configured to filter light emitted from the emission structure EMS, thereby selectively outputting light of a wavelength band or a color, which corresponds to each sub-pixel SP. The color filter layer CFL may include color filters CF respectively corresponding to the first to third sub-pixels SP1 to SP3. Each of the color filters CF may allow light having a wavelength band corresponding to a corresponding sub-pixel SP to pass therethrough. For example, a color filter CF corresponding to the first sub-pixel SP1 may allow light of a red color to pass therethrough, a color filter CF corresponding to the second sub-pixel SP2 may allow light of a green color to pass therethrough, and a color filter CF corresponding to the third sub-pixel SP3 may allow light of a blue color to pass therethrough. According to light emitted from the emission structure EMS in each sub-pixel SP, at least some of the color filters CF may be omitted.

The lens array LA may be disposed on the color filter layer CFL. The lens array LA may include lenses LS respectively corresponding to the first to third sub-pixels SP1 to SP3. Each of the lenses LS may output light emitted from the emission structure EMS along an intended path, thereby improving light emission efficiency. The lens array LA may have a relatively high refractive index. For example, the lens array LA may have a refractive index higher than a refractive index of the overcoat layer OC. In some embodiments, the lenses LS may include an organic material. In some embodiments, the lenses LS may include an acryl-based material. However, the material of the lenses LS is not limited thereto.

In some embodiments, as compared with the opening OP of the pixel defining layer PDL, at least some of the color filters CF of the color filter layer CFL and at least some of the lenses LS of the lens array LA may be shifted in a direction parallel to a plane defined by the first and second directions DR1 and DR2. For example, in a central area of the display area DA (see, e.g., FIG. 4), a center of a color filter CF and a center of a lens LS may be aligned or overlap with a center of a corresponding opening OP of the pixel defining layer PDL. For example, in the central area of the display area DA, the opening OP of the pixel defining layer PDL may completely overlap with the corresponding color filter CF of the color filter layer CFL and the corresponding lens LS of the lens array LA. In an area of the display area DA, which is adjacent to the non-display area NDA, the center of a color filter CF and the center of a lens LS may be shifted in a planar direction from the center of an opening OP of the pixel defining layer PDL. For example, in the area of the display area DA, which is adjacent to the non-display area NDA, the opening OP of the pixel defining layer PDL may partially overlap with the corresponding color filter CF of the color filter layer CFL and the corresponding lens LS of the lens array LA. Accordingly, in the center of the display area DA, light emitted from the emission structure EMS can be effectively output in a normal direction of the display surface. At an outer portion of the display area DA, light emitted from the emission structure EMS can be effectively output in a direction inclined by a predetermined angle with respect to the normal direction of the display surface.

The overcoat layer OC may be disposed over the lens array LA. The overcoat layer OC may cover the optical functional layer OFL, the encapsulation layer TFE, the emission structure EMS, and/or the pixel circuit layer PCL. The overcoat layer OC may include various materials suitable for protecting lower layers thereof from foreign matters such as dust and moisture. For example, the overcoat layer OC may include at least one of an inorganic insulating layer and an organic insulating layer. For example, the overcoat layer OC may include epoxy resin, but embodiments are not limited thereto. The overcoat layer OC may have a refractive index lower than a refractive index of the lens array LA.

The cover window CW may be disposed on the overcoat layer OC. The cover window CW may be configured to protect lower layers thereof. The cover window CW may have a refractive index higher than the refractive index of the overcoat layer OC. The cover window CW may include glass, but embodiments are not limited thereto. For example, the cover window CW may be an encapsulation glass configured to protect components disposed thereunder. In some other embodiments, the cover window CW may be omitted.

A display device 100 including a capacitor structure in accordance with some embodiments of the present disclosure will be described with reference to FIGS. 6 to 12. For convenience of description, descriptions of portions overlapping with the above-described portions will be simplified or will not be repeated.

First, a sectional structure of a pixel circuit layer PCL in which circuit elements of a sub-pixel circuit SPC is provided in accordance with some embodiments of the present disclosure will be described with reference to FIG. 6.

FIG. 6 is a schematic sectional view illustrating a pixel circuit layer according to some embodiments of the present disclosure.

In some embodiments, the pixel circuit layer PCL may include a substrate SUB, and include conductive layers CL, conductive structure layers M, interlayer insulating layers ILD, upper insulating layers UIL, and an upper conductive layer UCL.

In some embodiments, circuit elements of the sub-pixel circuit SPC may be patterned on the substrate SUB.

For example, the substrate SUB may be a silicon substrate, and a well WL formed through an ion implantation process may be disposed in the substrate SUB. A region of the well WL may form a source region of each of the transistors T1 to T4, another region of the well WL may form a drain region of each of the transistors T1 to T4, and still another region of the well WL may form a channel region of each of the transistors T1 to T4.

In some embodiments, the conductive layers CL may form an electrode electrically connected to the source/drain region of each of the transistors T1 to T4, and form a gate electrode of each of the transistors T1 to T4. For example, at least a portion of the conductive layers CL may be electrically connected to the well WL through a contact member CNP. In addition, at least a portion of the conductive layers CL may form at least a portion of each of the above-described first to third nodes N1 to N3. In addition, at least a portion of the conductive structure layer M may form at least a portion of each of the above-described first to third nodes N1 to N3. Accordingly, the substrate SUB, the conductive layers CL, and the conductive structure layers M on the substrate SUB may form the sub-pixel circuit SPC (see, e.g., FIG. 2).

In some embodiments, portions of the well WL, the conducive layers CL, and the conductive structure layers M may be electrically connected to each other through a contact member CNP penetrating at least one of the interlayer insulating layers ILD and the upper insulating layers UIL. In some embodiments, the upper conductive layer UCL may be electrically connected to at least a portion of the conductive layers CL and the conductive structure layers M. Accordingly, the upper conductive layer UCL may electrically connect the sub-pixel circuit SPC to the anode electrode AE of the light-emitting element LD.

In some embodiments, the conductive layers CL may include first and second conductive layers CL1 and CL2. In some embodiments, the interlayer insulating layers ILD may include first to third interlayer insulating layers ILD1 to ILD3. In some embodiments, the conductive structure layers M may include first to fourth conductive structure layers M1 to M4. In some embodiments, the upper insulating layers UIL may include first to fourth upper insulating layers UIL1 to UIL4. However, the present disclosure is not limited thereto. The number of layers forming each of the conductive layers CL, the conductive structure layers M, the interlayer insulating layers ILD, and the upper insulating layers UIL may be appropriately changed.

In some embodiments, the first to third interlayer insulating layers ILD1 to ILD3 and the first to fourth upper insulating layers UIL1 to UIL4 may be respectively disposed between portions of the substrate SUB, the first and second conductive layers CL1 and CL2, the first to fourth conductive structure layers M1 to M4, and the upper conductive layer UCL.

In some embodiments, the conductive layers CL and the conductive structure layers M may include various suitable conductive materials. The interlayer insulating layers ILD and the upper insulating layers UIL may include an inorganic material. However, the present disclosure is not limited thereto.

In some embodiments, the conductive structure layers M may be spaced apart from the substrate SUB, and secure a facing area between first and second capacitor electrodes forming the capacitors C1 to C3. Accordingly, the conductive structure layers M may enable a sufficient capacitance to be formed in the sub-pixel circuit SPC.

The conductive structure layers M may be adjacent to the conductive layers CL adjacent to the substrate SUB in a thickness direction of the substrate SUB (e.g., a vertical direction as the third direction DR3), and form capacitances of the capacitors C1 to C3 at different heights from the conductive layers CL. Accordingly, the capacitance of the sub-pixel circuit SPC can be relatively sufficiently formed in a relative narrow area.

A portion of the conductive structure layers M may be the first node N1 (see, e.g., FIG. 3), and another portion of the conductive structure layers M may be the third node N3 (see, e.g., FIG. 3). A portion of the conductive structure layers M may be the third node N3, and another portion of the conductive structure layers M may be electrically connected to the fourth power line PL4. A portion of the conductive structure layers M may be the second node N2 (see, e.g., FIG. 3), and another portion of the conductive structure layers M may be the third node N3.

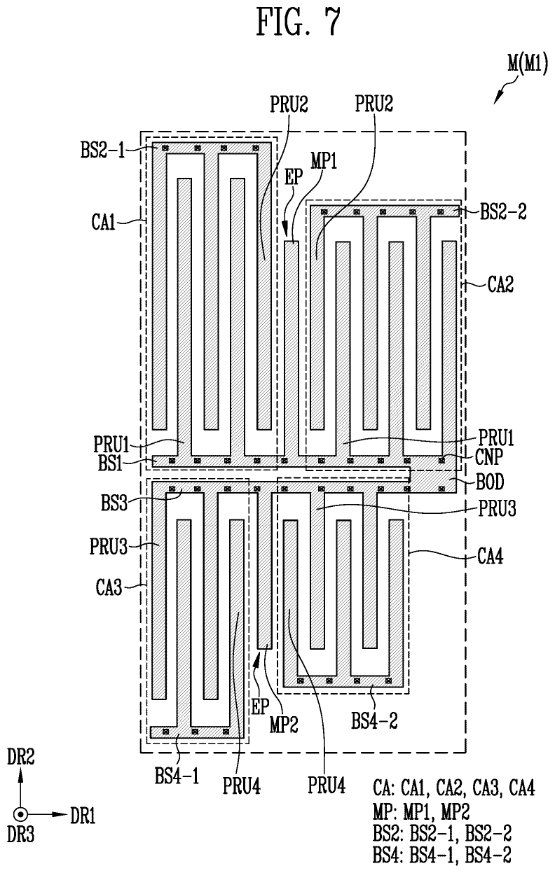

A planar structure in which the conductive structure layer M forms capacitors C1 to C3 in accordance with some embodiments of the present disclosure will be described with reference to FIGS. 7 to 10.

FIGS. 7 to 10 are schematic plan views illustrating a conductive structure layer according to some embodiments of the present disclosure.

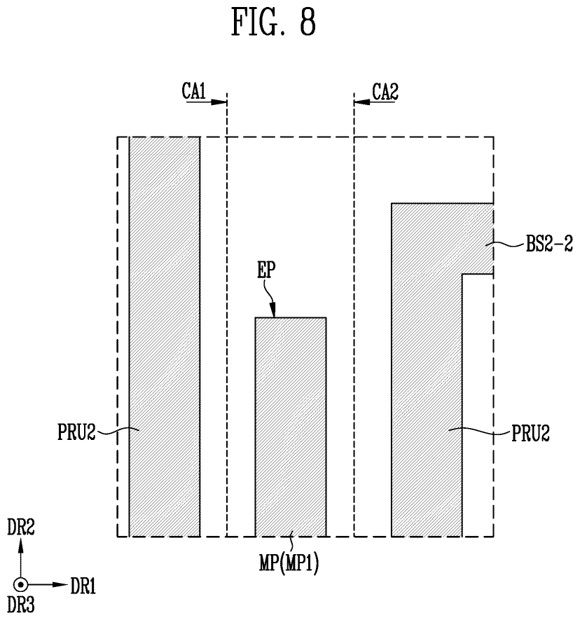

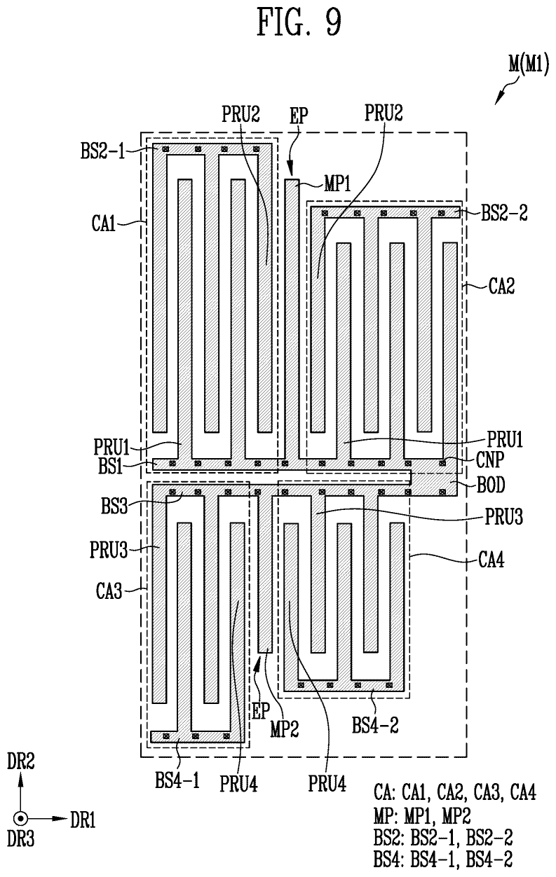

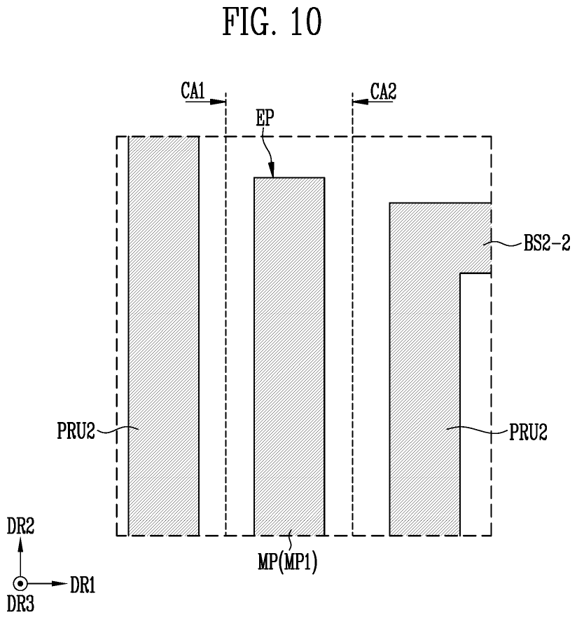

FIGS. 7 and 8 are a schematic plan view illustrating a capacitance area CA in accordance with some embodiments of the present disclosure, and FIG. 8 is a schematic enlarged view illustrating first and second capacitance areas CA1 and CA2. FIGS. 9 and 10 are schematic plan views illustrating a capacitance area CA in accordance with some embodiments of the present disclosure, and FIG. 10 is a schematic enlarged view illustrating first and second capacitance areas CA1 and CA2.

As described above, at least a portion of the conductive structure layers M may form the capacitors C1 to C3. Each of the conductive structure layers M may include capacitor electrodes spaced apart from each other on a plane to form a capacitance.

For convenience of description, FIGS. 7 to 10 are illustrated based on the first conductive structure layer M1 among the first to fourth conductive structure layers M1 to M4. However, technical portions which will be described later with reference to FIGS. 7 to 10 may be substantially equally applied to each of the first to fourth conductive structure layers M1 to M4.

In some embodiments, a conductive structure layer M may be patterned in a capacitance area CA and an area adjacent thereto. In some embodiments, the capacitance area CA may include first to fourth capacitance areas CA1 to CA4. However, the present disclosure is not limited thereto, and the number of capacitance areas CA may be changed.

The conductive structure layer M may form a capacitance in each of the first to fourth capacitance areas CA1 to CA4. For example, in each of the first to fourth capacitance areas CA1 to CA4, a portion of the conductive structure layer M may be one of the first to third nodes N1 to N3, and another portion of the conductive structure layer M may be another of the first to third nodes N1 to N3.

In some embodiments, each of the capacitance areas CA may have an approximately rectangular shape. However, the present disclosure is not limited thereto.

In some embodiments, at least some of the capacitance areas CA may have different areas. However, the present disclosure is not necessarily limited thereto. In some embodiments, at least some of the capacitance areas CA may have the same or substantially the same area.

In some embodiments, the conductive structure layer M may include first to fourth base portions BS1 to BS4, first to fourth protrusion portions PRU1 to PRU4, a middle portion MP, and a body portion BOD. The middle portion MP may include a first middle portion MP1 and a second middle portion MP2.

The middle portion MP may be designated as a finger electrode. The middle portion MP may be designated as a protrusion electrode.

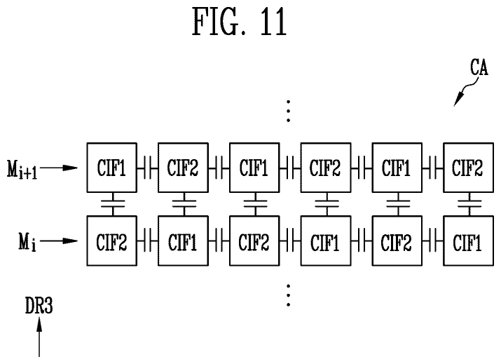

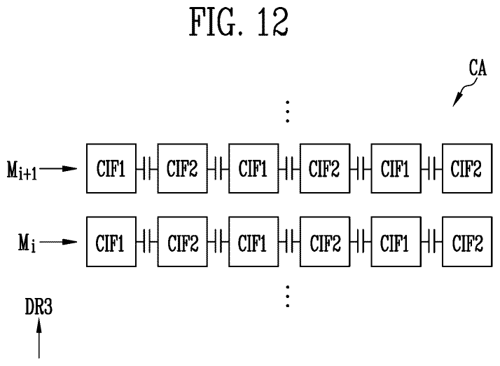

The first base portion BS1 may extend in a first direction DR1. The first base portion BS1 may be disposed throughout the first capacitance area CA1 and the second capacitance area CA2. First charge information CIF1 (see, e.g., FIG. 11 and FIG. 12) may be stored in the first base portion BS1.

The first capacitance area CA1 and the second capacitance area CA2 may be adjacent to each other along the first direction DR1.

The first base portion BS1 may be integrally formed with the body portion BOD. Accordingly, the first base portion BS1 may form the same node with conductive portions electrically connected to the body portion BOD.

In some embodiments, the first base portion BS1 may be electrically connected to other conductive portions in the pixel circuit layer PCL through contact members CNP, and form one node of the sub-pixel circuit SPC.

The second base portion BS2 may be spaced apart from the first base portion BS1 in a second direction DR2 different from the first direction DR1. The second base portion BS2 may extend in the first direction DR1. Second charge information CIF2 (see, e.g., FIGS. 11 and 12) different from the first charge information CIF1 may be stored in the second base portion BS2.

In some embodiments, the first charge information CIF1 and the second charge information CIF2 may have different charge amounts, and have different voltage intensities.

The second base portion BS2 may be physically spaced apart from the body portion BOD, and may not be electrically connected to the body portion BOD. Accordingly, the second base portion BS2 may form a node different from conductive portions electrically connected to the body portion BOD.

In some embodiments, the second base portion BS2 may be electrically connected to other conductive portions in the pixel circuit layer PCL through contact members CNP, and form an opposite node of the sub-pixel circuit SPC.

The second base portion BS2 may include a (2-1)th base portion BS2-1 and a (2-2)th base portion BS2-2. The (2-1)th base portion BS2-1 may be disposed in the first capacitance area CA1. The (2-2)th base portion BS2-2 may be disposed in the second capacitor area CA2.

The (2-1)th base portion BS2-1 and the (2-2)th base portion BS2-2 may be spaced apart from the first base portion BS1 at different distances along the second direction DR2. For example, the (2-2)th base portion BS2-2 may be closer the first base portion BS1 than the (2-1)th base portion BS2-1 in the second direction DR2.

The first protrusion portion PRU1 may be integrally formed with the first base portion BS1. The first protrusion portion PRU1 may extend in the second direction DR2. Like the first base portion BS1, the first charge information CIF1 may be stored in the first protrusion portion PRU1.

Some of the first protrusion portions PRU1 may extend from portions of the first base portion BS1 in the first capacitance area CA1, and others of the first protrusion portions PRU1 may extend from portions of the first base portion BS1 in the second capacitance area CA2.

The first protrusion portions PRU1 in the first capacitance area CA1 and the first protrusion portions PRU1 in the second capacitance area CA2 may have different lengths from each other in the second direction DR2.

The second protrusion portion PRU2 may be integrally formed with the second base portion BS2. The second protrusion portion PRU2 may extend in the second direction DR2. Like the second base portion BS2, the second charge information CIF2 may be stored in the second protrusion portion PRU2.

Some of the second protrusion portions PRU2 may extend from portions of the (2-1)th base portion BS2-1 in the first capacitance area CA1, and others of the second protrusion portions PRU2 may extend from portions of the (2-2)th base portion BS2-2 in the second capacitance area CA2.

The second protrusion portions PRU2 in the first capacitance area CA1 and the second protrusion portions PRU2 in the second capacitance area CA2 may have different length along the second direction DR2.

In some embodiments, in the first capacitance area CA1 and the second capacitance area CA2, different nodes may be adjacent to each other, and a capacitance may be formed. In some embodiments, the first base portion BS1, the first protrusion portions PRU1 and the first middle portion MP1 may form the same first node portion, and the second base portion BS2 and the second protrusion portions PRU2 may form the same second node portion.

For example, conductive portions (i.e., the first protrusion portions PRU1 and the first base portion BS1) to which the first charge information CIF1 is provided and conductive portions (i.e., the second protrusion portions PRU2 and the second base portion BS2) to which the second charge information CIF2 is provided may face each other in each of the first capacitance area CA1 and the second capacitance area CA2. For example, the first protrusion portions PRU1 and the second protrusion portions PRU2 may face each other in each of the first capacitance area CA1 and the second capacitance area CA2.

The first middle portion MP1 may be disposed between the first capacitance area CA1 and the second capacitance area CA2. The first middle portion MP1 may be integrally formed with the first base portion BS1. The first middle portion MP1 may extend in the second direction DR2. Like the first base portion BS1, the first charge information CIF1 may be stored in the first middle portion MP1.

One side of the first middle portion MP1 may be adjacent to the first capacitance area CA1, and face one of the second protrusion portions PRU2 in the first capacitance are CA1. Accordingly, the first middle portion MP1 may form a capacitance with the second protrusion portion PRU2 in the first capacitance area CA1.

The other side of the first middle portion MP1 may be adjacent to the second capacitance area CA2, and face one of the second protrusion portions PRU2 in the second capacitance area CA2. Accordingly, the first middle portion MP1 may form a capacitance with the second protrusion portion PRU2 in the second capacitance area CA2.

An end portion EP of the first middle portion MP1 may be disposed between the first capacitance area CA1 and the second capacitance area CA2.

The first middle portion MP1 may not overlap with the second base portion BS2 along the second direction DR2. The first middle portion MP1 may not overlap with the (2-1)th base portion BS2-1 and the (2-2)th base portion BS2-2 along the second direction DR2.

In some embodiments, as a length of the first middle portion MP1 along the second direction DR2 is adjusted during a manufacturing process of the display device 100, the first middle portion MP1 may be patterned to have a predetermined length.

In some embodiments, the first middle portion MP1 may form a capacitance while facing the second protrusion portion PRU2 in the first capacitance area CA1 and the second protrusion portion PRU2 in the second capacitance area CA2. The first middle portion MP1 may form a capacitance with the (2-2)th base portion BS2-2 or may not substantially form the capacitance according to the length of the first middle portion MP1. Also, the first middle portion MP1 may form a capacitance with a portion of the second protrusion portion PRU2 in the first capacitance area CA1 or may not substantially form the capacitance according to the length of the first middle portion MP1.

For example, (see FIGS. 7 and 8), the first middle portion MP1 may have a relatively short length, and overlap with the second protrusion portion PRU2 in the first capacitance area CA1 along the first direction DR1 and overlap with the second protrusion portion PRU2 in the second capacitance area CA2 along the first direction DR1. In some embodiments, the first middle portion MP1 may not overlap with the (2-1)th base portion BS2-1 and the (2-2)th base portion BS2-2 along the first direction DR1. The end portion EP of the first middle portion MP1 may overlap with the second protrusion portions PRU2 in each of the first and second capacitance areas CA1 and CA2 along the first direction DR1.

The first middle portion MP1 may form a capacitance with the second protrusion portions PRU2 at both sides thereof. Accordingly, as the length of the first middle portion MP1 is adjusted during the manufacturing process of the display device 100, the magnitude of the capacitance can be minutely adjusted (e.g., adjusted with suitable precision).

In some embodiments (see FIGS. 9 and 10), the first middle portion MP1 may have a relatively long length, and overlap with the second protrusion portion PRU2 in the first capacitance area CA1 along the first direction DR1 and entirely overlap with the second protrusion portion PRU2 in the second capacitance area CA2 along the first direction DR1. In some embodiments, the first middle portion MP1 may not overlap with the (2-1)th base portion BS2-1 along the first direction DR1, and may overlap with the (2-2)th base portion BS2-2 along the first direction DR1. The end portion EP of the first middle portion MP1 may overlap with the second protrusion portion PRU2 in the first capacitance area CA1 along the first direction DR1, and may not overlap with the second protrusion portion PRU2 and the (2-2)th base portion BS2-2 in the second capacitance area CA2 along the first direction DR1.

A portion of the first middle portion MP1 may form a capacitance with the second protrusion portions PRU2 at both sides thereof, and another portion of the first middle portion MP1 may form the capacitance with the second protrusion portion PRU2 in the first capacitance area CA1 at only one side thereof. Accordingly, as the length of the first middle portion MP1 is adjusted during the manufacturing process of the display device 100, the magnitude of the capacitance can be more minutely adjusted.

In some embodiments, the body portion BOD may attach the first base portion BS1 and a third base portion BS3 to each other. In other words, the first base portion BS1 and the third base portion BS3 may be connected by the body portion BOD. The body portion BOD may be disposed at an edge of the first base portion BS1 and the third base portion BS3.

In some embodiments, the first to fourth base portions BS1 to BS4 and the body portion BOD may be electrically connected to conductive portions formed in different layers through contact members CNP, and accordingly, conductive paths of the sub-pixel circuit SPC can be appropriately formed.

The third base portion BS3 may extend in the first direction DR1. The third base portion BS3 may be disposed throughout the third capacitance area CA3 and the fourth capacitance area CA4. The first charge information CIF1 may be stored in the third base portion BS3.

The third capacitance area CA3 and the fourth capacitance area CA4 may be adjacent to each other along the first direction DR1. The third capacitance area CA3 may be adjacent to the first capacitance area CA1 along the second direction DR2. The fourth capacitance area CA4 may be adjacent to the second capacitance area CA2 along the second direction DR2.

The third base portion BS3 may be integrally formed with the body portion BOD. Accordingly, the third base portion BS3 may form the same node with conductive portions electrically connected to the body portion BOD.

In some embodiments, the third base portion BS3 may be electrically connected to other conductive portions in the pixel circuit layer PCL through contact members CNP, and form one node of the sub-pixel circuit SPC.

The fourth base portion BS4 may be spaced apart from the third base portion BS3 in the second direction DR2 different from the first direction DR1. The fourth base portion BS4 may extend in the first direction DR1. The second charge information CIF2 different from the first charge information CIF1 may be stored in the fourth base portion BS4.

The fourth base portion BS4 may be physically spaced apart from the body portion BOD, and may not be electrically connected to the body portion BOD. Accordingly, the fourth base portion BS4 may form a node different from conductive portions electrically connected to the body portion BOD.

In some embodiments, the fourth base portion BS4 may be electrically connected to other conductive portions in the pixel circuit layer PCL through contact members CNP, and form an opposite node of the sub-pixel circuit SPC.

The fourth base portion BS4 may include a (4-1)th base portion BS4-1 and a (4-2)th base portion BS4-2. The (4-1)th base portion BS4-1 may be disposed in the third capacitance area CA3. The (4-2)th base portion BS4-2 may be disposed in the fourth capacitance area CA4.

The (4-1)th base portion BS4-1 and the (4-2)th base portion BS4-2 may be spaced apart from the third base portion BS3 at different distances in the second direction DR2. For example, the (4-2)th base portion BS4-2 may be closer the third base portion BS3 than the (4-1)th base portion BS4-1 is to the third base portion BS3.

The third protrusion portion PRU3 may be integrally formed with the third base portion BS3. The third protrusion portion PRU3 may extend in the second direction DR2. Like the third base portion BS3, the first charge information CIF1 may be stored in the third protrusion portion PRU3.

Some of the third protrusion portions PRU3 may extend from portions of the third base portion BS3 in the third capacitance area CA3, and others of the third protrusion portions PRU3 may extend from portions of the third base portion BS3 in the fourth capacitance area CA4.

The third protrusion portions PRU3 in the third capacitance area CA3 and the third protrusion portions PRU3 in the fourth capacitance area CA4 may have different lengths in the second direction DR2.

The fourth protrusion portion PRU4 may be integrally formed with the fourth base portion BS4. The fourth protrusion portion PRU4 may extend in the second direction DR2. Like the fourth base portion BS4, the second charge information CIF2 may be stored in the fourth protrusion portion PRU4.

Some of the fourth protrusion portions PRU4 may extend from portions of the (4-1)th base portion BS4-1 in the third capacitance area CA3, and others of the fourth protrusion portions PRU4 may extend from a portion of the (4-2)th base portion BS4-2 in the fourth capacitance area CA4.

The fourth protrusion portions PRU4 in the third capacitance area CA3 and the fourth protrusion portions PRU4 in the fourth capacitance area CA4 may have different length along the second direction DR2.

In some embodiments, in the third capacitance area CA3 and the fourth capacitance area CA4, different nodes may be adjacent to each other, and a capacitance may be formed. In some embodiments, the third base portion BS3, the third protrusion portions PRU3, and the second middle portion MP2 may form the same first node portion, and the fourth base portion BS4 and the fourth protrusion portions PRU4 may form the same second node portion.

For example, conductive portions (e.g., the third protrusion portions PRU3 and the third base portion BS3) to which the first charge information CIF1 is provided and conductive portions (e.g., the fourth protrusion portions PRU4 and the fourth base portion BS4) to which the second charge information CIF2 is provided may face each other in each of the third capacitance area CA3 and the fourth capacitance area CA4. For example, the third protrusion portions PRU3 and the fourth protrusion portions PRU4 may face each other in each of the third capacitance area CA3 and the fourth capacitance area CA4.

The second middle portion MP2 may be disposed between the third capacitance area CA3 and the fourth capacitance area CA4. The second middle portion MP2 may be integrally formed with the third base portion BS3. The second middle portion MP2 may extend in the second direction DR2. Like the third base portion BS3, the first charge information CIF1 may be stored in the second middle portion MP2.

One side of the second middle portion MP2 may be adjacent to the third capacitance area CA3, and face one of the fourth protrusion portions PRU4 in the third capacitance area CA3. Accordingly, the second middle portion MP2 may form a capacitance with the fourth protrusion portion PRU4 in the third capacitance area CA3.

The other side of the second middle portion MP2 may be adjacent to the fourth capacitance area CA4, and face one of the fourth protrusion portions PRU4 in the fourth capacitance area CA4. Accordingly, the second middle portion MP2 may form a capacitance with the fourth protrusion portion PRU4 in the fourth capacitance area CA4.

An end portion EP of the second middle portion MP2 may be disposed between the third capacitance area CA3 and the fourth capacitance area CA4.

The second middle portion MP2 may not overlap with the fourth base portion BS4 along the second direction DR2. The second middle portion MP2 may not overlap with the (4-1)th base portion BS4-1 and the (4-2)th base portion BS4-2 along the second direction DR2.

In some embodiments, as a length of the second middle portion MP2 along the second direction DR2 is adjusted during the manufacturing process of the display device 100, the second middle portion MP2 may be patterned to have a set length (e.g., a preset or predetermined length).

In some embodiments, the second middle portion MP2 may form a capacitance while facing the fourth protrusion portion PRU4 in the third capacitance area CA3 and the fourth protrusion portion PRU4 in the fourth capacitance area CA4. The second middle portions MP2 may form a capacitance with the (4-2)th base portion BS4-2 or may not substantially form the capacitance according to the length of the second middle portion MP2. Also, the second middle portion MP2 may form a capacitance with a portion of the fourth protrusion portion PRU4 in the third capacitance area CA3 or may not substantially form the capacitance according to the length of the second middle portion MP2.

For example, the second middle portion MP2 may have a relatively short length, and overlap with the fourth protrusion portion PRU4 in the third capacitance area CA3 along the first direction DR1 and overlap with a portion of the fourth protrusion portion PRU4 in the fourth capacitance area CA4 along the first direction DR1.

In some embodiments, the second middle portion MP2 may have a relatively long length, and overlap with the fourth protrusion portion PRU4 in the third capacitance area CA3 along the first direction DR1 and entirely overlap with the fourth protrusion portion PRU4 in the fourth capacitance area CA4 along the first direction DR1. In some embodiments, the second middle portion MP2 may overlap with the (4-2)th base portion BS4-2 along the first direction DR1 and may not overlap with the (4-1)th base portion BS4-1 along the first direction DR1.

Similarly to as described above, as the length of the second middle portion MP2 is adjusted during the manufacturing process of the display device 100, the magnitude of the capacitance can be more minutely (e.g., precisely) adjusted.

As a result, in accordance with the embodiment of the present disclosure, the conductive structure layers M are efficiently disposed based on a predetermined pattern, so that an appropriate capacitance can be formed in a relatively narrow area. Further, because the magnitude of the capacitance can be thoroughly (e.g., suitably) adjusted, the reliability of an electrical signal in the display device 100 can be improved.

In addition, because the magnitude of the capacitance can be adjusted as the length of the middle portion MP is adjusted, the need for conductive patterns to be excessively patterned to adjust the magnitude of the capacitance can be reduced. In other words, the conductive patterns may no longer need to be excessively patterned in order to adjust the magnitude of the capacitance. Accordingly, a space in the pixel circuit layer PCL can be more efficiently used, and an area in which a connection structure between lines (e.g., a contact portion) is to be disposed can be further sufficiently secured.

In addition, because the conductive structure layer M forming the capacitors C1 to C3 can be thoroughly pattern in a relatively narrow area, the sub-pixels SP can be formed in a narrow area. Accordingly, the display device 100 having suitably high resolution characteristics can be provided.

Referring to FIGS. 11 and 12, the conductive structure layer M may form a capacitance in the capacitance area CA, based on various suitable structures.

FIGS. 11 and 12 are schematic views illustrating a capacitance relationship between conductive structure layers adjacent to each other in a vertical direction according to some embodiments of the present disclosure.

Referring to FIGS. 11 and 12, the conductive structure layer M, in accordance with some embodiments of the present disclosure, may include an ith conductive structure layer Mᵢ and an (i+1)th conductive structure layer Mᵢ₊₁, which are adjacent to each other in the vertical direction (e.g., the third direction DR3 or the thickness direction of the substrate SUB).

The ith conductive structure layer Mᵢ may be a conductive structure layer M of an ith layer among the conductive structure layers M, and the (i+1)th conductive structure layer Mᵢ₊₁ may be a conductive structure layer M of an (i+1)th layer among the conductive structure layers M. Here, i may be a natural number of 1 or more. When the total layer number of conductive structure layers M is n, i may be smaller than or equal to n−1.

In some embodiments (see, e.g., FIGS. 11 and 12), each of the ith conductive structure layer Mᵢ and the (i+1)th conductive structure layer Mᵢ₊₁ may have a structure in which a node to which the first charge information CIF1 is provided and a node to which the second charge information CIF2 is provided are alternatively disposed.

In some embodiments (see, e.g., FIG. 11), the ith conductive structure layer Mᵢ and the (i+1)th conductive structure layer Mᵢ₊₁ may form a capacitance in the vertical direction. For example, the ith conductive structure layer Mᵢ and the (i+1)th conductive structure layer Mᵢ₊₁ may include a structure in which nodes adjacent to each other in the vertical direction have different charge information CIF1 and CIF2.

In some embodiments (see, e.g., FIG. 12), the ith conductive structure layer Mᵢ and the (i+1)th conductive structure layer Mᵢ₊₁ may not form the capacitance in the vertical direction. For example, the ith conductive structure layer Mᵢ and the (i+1)th conductive structure layer Mᵢ₊₁ may include a structure in which nodes adjacent to each other in the vertical direction have the same charge information CIF1 or CIF2.

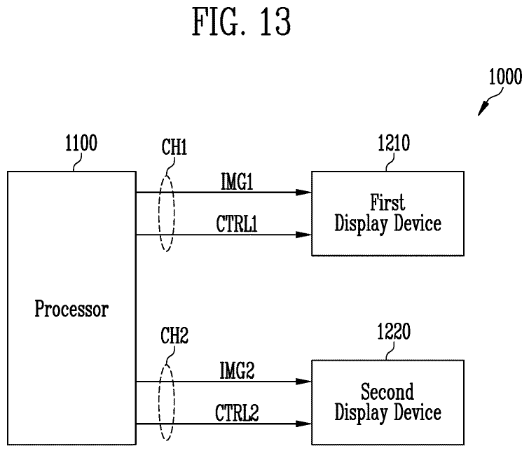

FIG. 13 is a block diagram illustrating an electronic device according to some embodiments of the present disclosure.

Referring to FIG. 13, an electronic device 1000 may include a processor 1100 and one or more display devices 1210 and 1220. The electronic device 1000 may implement a display system.

The processor 1100 may perform various tasks and various calculations. In some embodiments, the processor 1100 may include an Application Processor (AP), a Graphics Processing Unit (GPU), a microprocessor, a Central Processing Unit (CPU), and/or the like. The processor 1100 may be connected to other components of the electronic device 1000 through a bus system to control the components of the electronic device 1000.

According to an embodiment, the processor 1100 may provide input image data to the display device 1210, 1220, and the display device 1210, 1220 may display images based on the input image data provided by the processor 1100.

In some embodiments, the electronic device 1000 may include first and second display devices 1210 and 1220. The processor 1100 may be connected to the first display device 1210 through a first channel CH1, and may be connected to the second display device 1220 through a second channel CH2.

Through the first channel CH1, the processor 1100 may transmit first image data IMG1 and a first control signal CTRL1 to the first display device 1210. The first display device 1210 may display an image, based on the first image data IMG1 and the first control signal CTRL1. The first display device 1210 may be configured identically to the display device 100 described with reference to FIG. 1. The first image data IMG1 and the first control signal CTRL1 may be respectively provided as the input image data IMG and the control signal CTRL, which are shown in FIG. 1.

Through the second channel CH2, the processor 1100 may transmit second image data IMG2 and a second control signal CTRL2 to the second display device 1220. The second display device 1220 may display an image, based on the second image data IMG2 and the second control signal CTRL2. The second display device 1220 may be configured identically to the display device 100 described with reference to FIG. 1. The second image data IMG2 and the second control signal CTRL2 may be respectively provided as the input image data IMG and the control signal CTRL, which are shown in FIG. 1.

The electronic device 1000 may include a computing system for providing an image display function, such as a portable computer, a mobile phone, a smartphone, a tablet personal computer (PC), a smart watch, a watch phone, a portable multimedia player (PMP), a navigation system, an ultra mobile computer (UMPC), or the like. The electronic device 1000 may include at least one of a head mounted display (HMD) device, a virtual reality (VR) device, a mixed reality (MR) device, and an augmented reality (AR) device.

According to an embodiment, the electronic device 1000 may further include a memory device, a storage device, an input/output (I/O) device, and/or a power supply.

The memory device may store data needed to perform the operation of the electronic device 1000. The memory device may function as a working memory and/or a buffer memory for the processor. For example, the memory device may include one or more volatile memory devices such as a dynamic random access memory (DRAM) device, a static random access memory (SRAM) device, and a mobile DRAM device.

The storage device may store data in response to control signals or data from the processor. The storage device may include one or more non-volatile storages to retain the data even when the electronic device 1000 is powered off. In some embodiments, the storage device may include a solid state drive (SSD), a hard disk drive (HDD), a CD-ROM, or the like.

The I/O device may include input devices such as a keyboard, a keypad, a touchpad, a touch screen, and a mouse, and output devices such as a speaker and a printer. In an embodiment, the display device 1210, 1220 may be included in the I/O device.

The power supply may supply power needed to perform the operation of the electronic device 1000. For example, the power supply may be a power management integrated circuit (PMIC). In an embodiment, the power supply may supply power to the display device 1210, 1220.

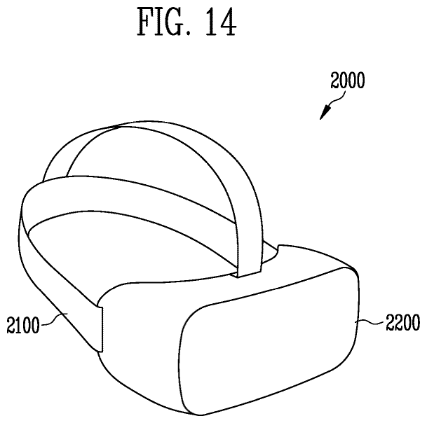

FIG. 14 is a perspective view illustrating an application example of the electronic device shown in FIG. 13 according to some embodiments of the present disclosure.

Referring to FIG. 14, the electronic device 1000 shown in FIG. 13 may be applied to a head mounted display device 2000. The head mounted display device 2000 may be a wearable electronic device which can be worn on a head of a user.

The head mounted display device 2000 may include a head mounting band 2100 and a display device accommodating case 2200. The head mounting band 2100 may be connected to the display device accommodating case 2200. The head mounting band 2100 may include a horizontal band and/or a vertical band, used to fix the head mounted display device 2000 to the head of the user. The horizontal band may be configured to surround a side portion of the head of the user, and the vertical band may be configured to surround an upper portion of the head of the user. However, embodiments are not limited thereto. For example, the head mounting band 2100 may be implemented in the form of a glasses frame, a helmet, or the like.

The display device accommodating case 2200 may accommodate the first and second display devices 1210 and 1220 shown in FIG. 13. The display device accommodating case 2200 may further accommodate the processor 1100 shown in FIG. 13.

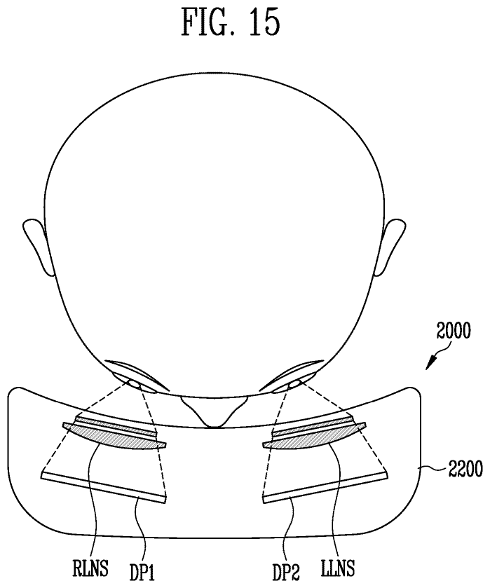

FIG. 15 is a view illustrating the head-mounted display device shown in FIG. 14, which is worn by a user, according to some embodiments of the present disclosure.

Referring to FIG. 15, a first display panel DP1 of the first display device 1210 and a second display panel DP2 of the second display device 1220 may be disposed in the head mounted display device 2000. The head mounted display device 2000 may further include one or more lenses LLNS and RLNS.

In the display device accommodating case 2200, a right-eye lens RLNS may be disposed between the first display panel DP1 and a right eye of the user. In the display device accommodating case 2200, a left-eye lens LLNS may be disposed between the second display panel DP2 and a left eye of the user.

An image output from the first display panel DP1 may be viewed by the right eye of the user through the right-eye lens RLNS. The right-eye lens RLNS may refract light emitted from the first display panel DP1 to face the right eye of the user. The right-eye lens RLNS may perform an optical function for adjusting a viewing distance between the first display panel DP1 and the right eye of the user.

An image output from the second display panel DP2 may be viewed by the left eye of the user through the left-eye lens LLNS. The left-eye lens LLNS may refract light emitted from the second display panel DP2 to face the left eye of the user. The left-eye lens LLNS may perform an optical function for adjusting a viewing distance between the second display panel DP2 and the left eye of the user.

In some embodiments, each of the right-eye lens RLNS and the left-eye lens LLNS may include an optical lens having a pancake-shaped section. In some embodiments, each of the right-eye lens RLNS and the left-eye lens LLNS may include a multi-channel lens including sub-areas having different optical characteristics. Each display panel DP1 and DP2 may output images respectively corresponding to the sub-areas of the multi-channel lens, and the output images may be viewed by the user while respectively passing through corresponding sub-areas.

In accordance with the present disclosure, there can be provided a display device in which the magnitude of capacitance of a capacitor can be thoroughly controlled, thereby improving the reliability of an electrical signal in the display device.

In accordance with the present disclosure, there can be provided a display device capable of having high resolution characteristics.

In accordance with the present disclosure, there can be provided a display device in which an area having a circuit element disposed therein can be efficiently used.

It should be understood that embodiments described herein should be considered in a descriptive sense and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims and equivalents thereof.

What is claimed is:

1. A display device comprising:
a pixel circuit layer comprising a conductive structure layer on a substrate; and
a light-emitting element on the pixel circuit layer,
wherein the conductive structure layer comprises:
a first base portion and a second base portion, extending in a first direction, the first base portion and the second base portion being spaced apart from each other;
first protrusion portions extending in a second direction different from the first direction, the first protrusion portions being integral with the first base portion;
second protrusion portions extending in the second direction, the second protrusion portions being integral with the second base portion; and
a first middle portion extending in the second direction,
wherein a portion of the first protrusion portions and a portion of the second protrusion portions are in a first capacitance area, and face each other,
wherein a portion of the first protrusion portions and a portion of the second protrusion portions are in a second capacitance area spaced apart from the first capacitance area in the first direction, and face each other, and
wherein the first middle portion is between the first capacitance area and the second capacitance area.

2. The display device of claim 1, wherein the first middle portion is integrally formed with the first base portion,
wherein the first base portion, the first protrusion portions, and the first middle portion form a first node portion to which a first charge information is provided, and
wherein the second base portion and the second protrusion portions form a second node portion to which a second charge information is provided, the second charge information being different from the first charge information.

3. The display device of claim 1, wherein some of the first protrusion portions, which are in the first capacitance area, and others of the first protrusion portions, which are in the second capacitance area, have different lengths, and
wherein some of the second protrusion portions, which are in the first capacitance area, and some others of the second protrusion portions, which are in the second capacitance area, have different lengths.

4. The display device of claim 1, wherein a first side of the first middle portion faces one of the second protrusion portions in the first capacitance area, and
wherein a second side of the first middle portion faces one of the second protrusion portions in the second capacitance area.

5. The display device of claim 1, wherein the second base portion comprises a (2-1)th base portion and a (2-2)th base portion, which are spaced apart from the first base portion at different distances with respect to the second direction.

6. The display device of claim 5, wherein the first middle portion overlaps with the second protrusion portions in the first capacitance area and the second capacitance area along the first direction, and
wherein the first middle portion does not overlap with the (2-1)th base portion and the (2-2)th base portion along the first direction.

7. The display device of claim 6, wherein an end portion of the first middle portion overlaps with the second protrusion portions in the first capacitance area and the second capacitance area along the first direction, and does not overlap with the (2-1)th base portion and the (2-2)th base portion along the first direction, and
wherein the first middle portion does not overlap with the (2-1)th base portion and the (2-2)th base portion along the second direction.

8. The display device of claim 5, wherein the first middle portion overlaps with the second protrusion portions in the first capacitance area along the first direction, and entirely overlaps with the second protrusion portions in the second capacitance area along the first direction.

9. The display device of claim 8, wherein an end portion of the first middle portion overlaps with the second protrusion portions in the first capacitance area along the first direction, and does not overlap with the second protrusion portions in the second capacitance area and the (2-2)th base portion along the first direction, and
wherein the first middle portion does not overlap with the (2-1)th base portion and the (2-2)th base portion along the second direction.

10. The display device of claim 1, wherein the conductive structure layer further comprises:
a third base portion and a fourth base portion, extending in the first direction, the third base portion and the fourth base portion, being spaced apart from each other;
third protrusion portions extending in the second direction, the third protrusion portions being integrally formed with the third base portion;
fourth protrusion portions extending in the second direction, the fourth protrusion portions being integrally formed with the fourth base portion; and
a second middle portion extending in the second direction,
wherein some of the third protrusion portions and some of the fourth protrusion portions are in a third capacitance area, and face each other,
wherein others of the third protrusion portions and others of the fourth protrusion portions are in a fourth capacitance area spaced apart from the third capacitance area in the first direction, and face each other,
wherein an end portion of the second middle portion is between the third capacitance area and the fourth capacitance area,
wherein the first capacitance area the third capacitance area are adjacent to each other in the second direction, and
wherein the second capacitance area and the fourth capacitance area are adjacent to each other in the second direction.

11. The display device of claim 10, wherein the conductive structure layer further comprises a body portion at one edge of the first base portion and the third base portion, the body portion being integrally formed with the first base portion and the third base portion, and
wherein the fourth base portion comprises a (4-1)th base portion and a (4-2)th base portion, which are spaced apart from the third base portion at different distances along the second direction.

12. The display device of claim 11, wherein the second middle portion overlaps with the fourth protrusion portions in the third capacitance area and the fourth capacitance area along the first direction, and does not overlap with the (4-1)th base portion and the (4-2)th base portion along the first direction, and
wherein the second middle portion does not overlap with the (4-1)th base portion and the (4-2)th base portion along the second direction.

13. The display device of claim 11, wherein the second middle portion overlaps with the fourth protrusion portions in the third capacitance area and the fourth capacitance area along the first direction, does not overlap with the (4-1)th base portion along the first direction, and overlaps with the (4-2)th base portion along the first direction, and
wherein the second middle portion does not overlap with the (4-1)th base portion and the (4-2)th base portion along the second direction.

14. The display device of claim 1, wherein the pixel circuit layer comprises a sub-pixel circuit electrically connected to the light-emitting element, the sub-pixel circuit being formed by conductive layers on the substrate, and
wherein the conductive structure layer comprises conductive structure layers on the conductive layers, the conductive structure layers being formed in a plurality of different layers.

15. The display device of claim 14, wherein the conductive structure layer comprises an ith conductive structure layer and an (i+1)th conductive structure layer, which are adjacent to each other in a thickness direction of the substrate, and
wherein the ith conductive structure layer and the (i+1)th conductive structure layer form a capacitance along the thickness direction.

16. The display device of claim 14, wherein the conductive structure layer comprises an ith conductive structure layer and an (i+1)th conductive structure layer, which are adjacent to each other in a thickness direction of the substrate, and
wherein the ith conductive structure layer and the (i+1)th conductive structure layer do not form any capacitance along the thickness direction.

17. The display device of claim 14, wherein the conductive structure layers comprise a first conductive structure layer, a second conductive structure layer, a third conductive structure layer, and a fourth conductive structure layer, which are arranged in different layers.

18. The display device of claim 1, wherein the pixel circuit layer comprises a sub-pixel circuit,
wherein the sub-pixel circuit comprises:
a first transistor connected between a first node and a second node, the first transistor comprising a gate electrode connected to a third node;
a second transistor connected between a data line and the third node, the second transistor comprising a gate electrode electrically connected to a first sub-gate line;
a third transistor connected between a first power line to which a first power voltage is supplied and the first node, the third transistor comprising a gate electrode electrically connected to an emission control line;
a fourth transistor connected between the second node and a third power line to which an initialization voltage is supplied, the fourth transistor comprising a gate electrode electrically connected to a second sub-gate line;
a first capacitor connected between the first node and the third node;
a second capacitor connected between the third node and a fourth power line to which a reference voltage is supplied; and
a third capacitor between the second node and the third node,
wherein the light-emitting element is connected between the second node and a second power line to which a second power voltage is supplied,
wherein a first portion of the conductive structure layer forms one of the first node, the second node, and the third node, and a second portion of the conductive structure layer forms another of the first node, the second node, and the third node,
wherein the substrate comprises silicon, and
wherein the light-emitting element is an organic light emitting diode.

19. A display device comprising:
a pixel circuit layer comprising a conductive structure layer on a substrate; and
a light-emitting element on the pixel circuit layer,
wherein the conductive structure layer comprises:
a first base portion and a second base portion, extending in a first direction, the first base portion and the second base portion, being spaced apart from each other;
first protrusion portions extending in a second direction different from the first direction, the first protrusion portions being integrally formed with the first base portion;
second protrusion portions extending in the second direction, the second protrusion portions being integrally formed with the second base portion; and
a middle portion extending in the second direction,
wherein the first protrusion portions, the second protrusion portions, the first base portion, and the second base portion are in capacitance areas adjacent to each other,
wherein the middle portion is between the adjacent capacitance areas, and
wherein the second base portion comprises a (2-1)th base portion and a (2-2)th base portion, which are spaced apart from the first base portion at different distances.

20. An electronic device comprising:
a processor configured to provide input image data;
a display device configured to display an image based on the input image data;
and
a power supply configured to supply power to the display device,
the display device comprising:
a pixel circuit layer comprising a conductive structure layer on a substrate; and
a light-emitting element on the pixel circuit layer,
wherein the conductive structure layer comprises:
a first base portion and a second base portion, extending in a first direction, the first base portion and the second base portion being spaced apart from each other;
first protrusion portions extending in a second direction different from the first direction, the first protrusion portions being integral with the first base portion;
second protrusion portions extending in the second direction, the second protrusion portions being integral with the second base portion; and
a first middle portion extending in the second direction,
wherein a portion of the first protrusion portions and a portion of the second protrusion portions are in a first capacitance area, and face each other,
wherein a portion of the first protrusion portions and a portion of the second protrusion portions are in a second capacitance area spaced apart from the first capacitance area in the first direction, and face each other, and
wherein the first middle portion is between the first capacitance area and the second capacitance area.
